(19) United States
(12) Patent Application Publication
(10) Pub. No.: US 2024/0276729 A1
(43) Pub. Date: Aug. 15, 2024

(54) SEMICONDUCTOR DEVICE AND METHOD OF FABRICATING THE SAME

(71) Applicant: SAMSUNG ELECTRONICS CO., LTD., SUWON-SI (KR)

(72) Inventors: CHANGMIN CHOI, SUWON-SI (KR); HYUNMIN KIM, SUWON-SI (KR); JUNTAEK PARK, SUWON-SI (KR); DONGJIN LEE, SUWON-SI (KR); RYOONGBIN LEE, SUWON-SI (KR); JUNHEE LIM, SUWON-SI (KR)

(21) Appl. No.: 18/511,597

(22) Filed: Nov. 16, 2023

(30) Foreign Application Priority Data
Feb. 10, 2023 (KR) 10-2023-0018283

(51) Int. Cl. H10B 43/40; H10B 43/27

(52) U.S. Cl. CPC H10B 43/40; H10B 43/27

(57) ABSTRACT

A semiconductor device includes a first substrate, a transistor disposed on the first substrate, and a first interconnection layer connected to the transistor. The first interconnection layer includes a first conductive line, a second conductive line, and a third conductive line, which are spaced apart from each other in a first direction parallel to a top surface of the first substrate. The second conductive line is disposed between the first conductive line and the third conductive line. A top surface of the second conductive line is located at a height higher than top surfaces of the first and third conductive lines with respect to the top surface of the first substrate.

### CROSS-REFERENCE TO RELATED APPLICATIONS

This U.S. non-provisional patent application claims priority under 35 U.S.C. § 119 to Korean Patent Application No. 10-2023-0018283, filed on Feb. 10, 2023, in the Korean Intellectual Property Office, the disclosure of which is incorporated by reference herein.

### 1. TECHNICAL FIELD

The present disclosure relates to a semiconductor device including interconnection patterns and a method of fabricating the same.

### 2. DISCUSSION OF RELATED ART

A semiconductor device is an electronic device that relies on the electrical properties of a semiconductor material for its function. A semiconductor device may be manufactured as an integrated circuit (IC) chip to include two or more electronic components manufactured and interconnected via conducting lines on a single semiconductor wafer (e.g., a substrate). In a semiconductor device, pitch is the spacing between the electronic components and the spacing between the conducting lines. In IC manufacturing, photolithography is a process that uses light to produce minutely patterned thin films of suitable materials over the substrate to form the electronic components and the conducting lines.

As semiconductor devices have recently become highly integrated and miniaturized, there is a growing demand for these electronic components and conducting lines to have a fine pitch and width. As a result, the importance of a photolithography process for forming fine patterns is increasing.

### SUMMARY

At least one embodiment of the inventive concept provides a method that overcomes technical difficulties in a process of patterning interconnection patterns and a semiconductor device fabricated thereby.

At least one embodiment of the inventive concept provides a method of increasing an integration density of interconnection patterns and a semiconductor device fabricated thereby.

According to an embodiment of the inventive concept, a semiconductor device includes a first substrate, a transistor disposed on the first substrate, and a first interconnection layer connected to the transistor. The first interconnection layer includes a first conductive line, a second conductive line, and a third conductive line, which are spaced apart from each other in a first direction parallel to a top surface of the first substrate. The second conductive line is disposed between the first conductive line and the third conductive line. A top surface of the second conductive line is located at a height higher than top surfaces of the first and third conductive lines with respect to the top surface of the first substrate.

According to an embodiment of the inventive concept, a method of fabricating a semiconductor device includes: forming a first lower insulating layer on a first substrate; forming a first interconnection trench and a third interconnection trench in the first lower insulating layer to be spaced apart from each other in a first direction parallel to a top surface of the first substrate; forming first sacrificial patterns to fill the first and third interconnection trenches, respectively; forming a second interconnection trench to penetrate a portion of each of the first sacrificial patterns and the first lower insulating layer between the first sacrificial patterns; forming a second sacrificial pattern to fill the second interconnection trench; removing the first sacrificial patterns to expose a portion of the first interconnection trench and a portion of the third interconnection trench; forming a first conductive line in the portion of the first interconnection trench and a third conductive line in the portion of the third interconnection trench; removing the second sacrificial pattern to expose the second interconnection trench; forming a first pattern insulating layer on the first lower insulating layer to fill a portion of the second interconnection trench; and forming a second conductive line on the first pattern insulating layer to fill a remaining portion of the second interconnection trench.

According to an embodiment of the inventive concept, a semiconductor device includes a first substrate, a peripheral circuit structure disposed on the first substrate, a second substrate disposed on the peripheral circuit structure, a stack including interlayer insulating layers and gate electrodes, which are alternatingly stacked on the second substrate, and first vertical channel structures penetrating the stack to be electrically connected to the second substrate. The peripheral circuit structure includes peripheral circuit transistors disposed on the first substrate and a first interconnection layer connected to the peripheral circuit transistors. The first interconnection layer includes a first conductive line, a second conductive line, and a third conductive line, which are spaced apart from each other in a first direction parallel to a top surface of the first substrate. The second conductive line is disposed between the first conductive line and the third conductive line. A top surface of the second conductive line is located at a level higher than top surfaces of the first and third conductive lines with respect to the top surface of the first substrate.

### BRIEF DESCRIPTION OF THE DRAWINGS

FIG. 1A is a plan view illustrating a semiconductor device according to an embodiment of the inventive concept.

FIGS. 1B to 1D are sectional views taken along lines I-I, II-II′, and III-III′ of FIG. 1A.

FIGS. 2A to 2J are sectional views, which are taken along the line I-I′ of FIG. 1A to illustrate a method of fabricating a semiconductor device, according to an embodiment of the inventive concept.

FIGS. 3A to 3J are sectional views, which are taken along the line II-II′ of FIG. 1A to illustrate a method of fabricating a semiconductor device, according to an embodiment of the inventive concept.

FIGS. 4A to 4C are sectional views, which are taken along the lines I-I′, II-II′, and III-III′ of FIG. 1A to illustrate a semiconductor device according to an embodiment of the inventive concept.

FIG. 5 is a diagram schematically illustrating an electronic system including a three-dimensional semiconductor memory device, according to an embodiment of the inventive concept.

FIG. 6 is a perspective view schematically illustrating an electronic system including a three-dimensional semiconductor memory device, according to an embodiment of the inventive concept.

FIGS. 7 and 8 are sectional views, which are respectively taken along lines I-I′ and II-II′ of FIG. 6 to illustrate a semiconductor package including a three-dimensional semiconductor memory device, according to an embodiment of the inventive concept.

FIG. 9 is a plan view illustrating a three-dimensional semiconductor memory device according to an embodiment of the inventive concept.

FIGS. 10A and 10B are sectional views, which are respectively taken along lines I-I′ and II-II′ of FIG. 9 to illustrate a three-dimensional semiconductor memory device according to an embodiment of the inventive concept.

FIG. 11A is an enlarged sectional view illustrating a portion of a three-dimensional semiconductor memory device according to an embodiment of the inventive concept and corresponding to a portion ‘A’ of FIG. 10A.

FIG. 11B is an enlarged sectional view illustrating a portion of a three-dimensional semiconductor memory device according to an embodiment of the inventive concept and corresponding to a portion ‘B’ of FIG. 10A.

FIG. 11C is an enlarged view illustrating a portion of a three-dimensional semiconductor memory device according to an embodiment of the inventive concept and corresponding to a portion ‘C’ of FIG. 10B.

FIGS. 12 to 20 are sectional views, which are taken along the line I-I′ of FIG. 9 to illustrate a method of fabricating a three-dimensional semiconductor memory device, according to an embodiment of the inventive concept.

FIG. 21 is a sectional view, which is taken along the line II-II′ of FIG. 9 to illustrate a three-dimensional semiconductor memory device according to an embodiment of the inventive concept.

### DETAILED DESCRIPTION

Example embodiments of the inventive concepts will now be described more fully with reference to the accompanying drawings, in which example embodiments are shown.

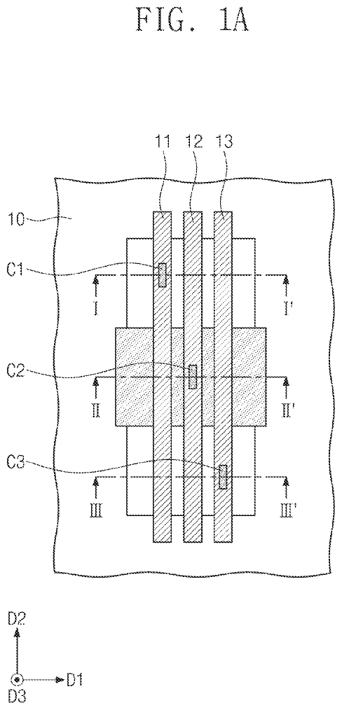

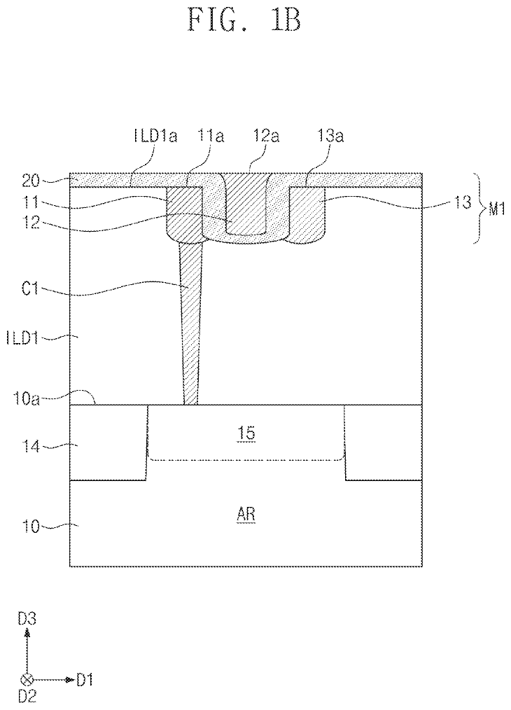

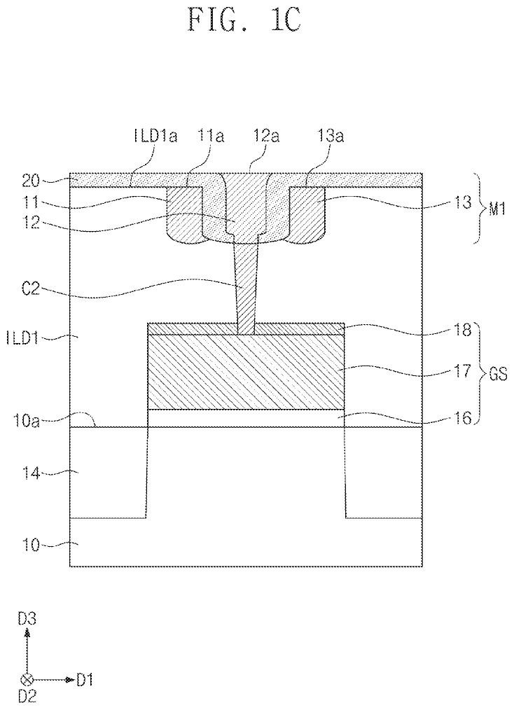

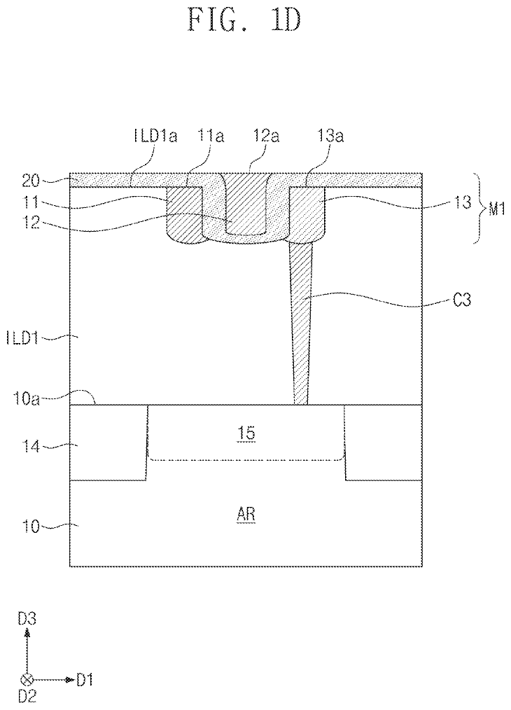

FIG. 1A is a plan view illustrating a semiconductor device according to an embodiment of the inventive concept. FIGS. 1B to 1D are sectional views taken along lines I-I, II-II′, and III-III′ of FIG. 1A.

Referring to FIGS. 1A to 1D, a semiconductor device may include a first substrate 10, a transistor disposed on the first substrate 10, and a first lower insulating layer ILD1 covering the transistor and the first substrate 10. The transistor may include a gate structure GS, which is disposed on the first substrate 10, and source/drain regions 15, which are disposed in the first substrate 10 and at both sides of the gate structure GS. In an embodiment, the gate structure GS includes a gate electrode 17 disposed on the first substrate 10, a gate dielectric layer 16 disposed between the first substrate 10 and the gate electrode 17, and a gate capping pattern 18 disposed on a top surface of the gate electrode 17. The gate structure GS may extend in a first direction D1, which is parallel to a top surface 10a of the first substrate 10. The source/drain regions 15 may be spaced apart from each other in a second direction D2, which is parallel to the top surface 10a of the first substrate 10 and is non-parallel to the first direction D1. The source/drain regions 15 may be spaced apart from each other in the second direction D2, with the gate structure GS interposed therebetween.

A first contact C1, a second contact C2, and a third contact C3, which are respectively and electrically connected to terminals of the transistor, may be provided in the first lower insulating layer ILD1. The first and third contacts C1 and C3 may be electrically connected to the source/drain regions 15, respectively, and the second contact C2 may be electrically connected to the gate electrode 17. For example, the second contact C2 may penetrate the gate capping pattern 18 to connect to the gate electrode 17.

A first conductive line 11, a second conductive line 12, and a third conductive line 13, which are respectively connected to the first to the third contacts C1, C2, and C3, may be disposed in the first lower insulating layer ILD1. The first, second, and third conductive lines 11, 12, and 13 may be disposed to cross the gate structure GS. The first, second, and third conductive lines 11, 12, and 13 may be spaced apart from each other in the first direction D1 and may extend in the second direction D2.

The first substrate 10 may be a silicon substrate, a silicon germanium substrate, a germanium substrate, or a structure including a single-crystalline silicon substrate and a single-crystalline epitaxial layer grown therefrom. A device isolation layer 14 may be disposed in the first substrate 10. The device isolation layer 14 may define an active region AR of the first substrate 10. The device isolation layer 14 may be formed of or include silicon oxide. The gate structure GS may be disposed on the active region AR, and the source/drain regions 15 may be disposed at both sides of the gate structure GS and in the active region AR.

The gate dielectric layer 16 may include a silicon oxide layer, a silicon nitride layer, and/or a silicon oxynitride layer. The gate electrode 17 may include a conductive material. In an embodiment, the conductive material may be one of doped semiconductor materials (e.g., doped silicon or doped germanium), conductive metal nitrides (e.g., titanium nitride or tantalum nitride), metallic materials (e.g., tungsten, titanium, or tantalum), and metal-semiconductor compounds (e.g., tungsten silicide, cobalt silicide, or titanium silicide). The gate capping pattern 18 may be formed of or include at least one of silicon oxide, silicon nitride, and/or silicon oxynitride.

The source/drain regions 15 may be regions generated by injecting impurities into the first substrate 10 (e.g., the active region AR). In the case where the transistor is a N-channel metal-oxide semiconductor (NMOS) transistor, the source/drain regions 15 may be formed of or include arsenic (As) or phosphorus (P). In the case where the transistor is a P-channel metal-oxide semiconductor (PMOS) transistor, the source/drain regions 15 may be formed of or include boron (B).

The first lower insulating layer ILD1 may be formed of or include at least one of silicon oxide, silicon nitride, silicon oxynitride, and/or low-k dielectric materials. The first to third contacts C1, C2, and C3 and the first to third conductive lines 11, 12, 13 may be formed of or include at least one of metallic materials (e.g., tungsten, titanium, and tantalum) and/or conductive metal nitride materials (e.g., titanium nitride, tantalum nitride, and tungsten nitride).

In an embodiment, a first pattern insulating layer 20 is interposed between the first and second conductive lines 11 and 12 and between the second and third conductive lines 12 and 13. The first pattern insulating layer 20 may extend along a bottom surface of the second conductive line 12. The second conductive line 12 may be formed to penetrate the first pattern insulating layer 20 to be connected to the second contact C2. The first pattern insulating layer 20 may extend to regions on a top surface 11a of the first conductive line 11 and a top surface 13a of the third conductive line 13 and may further extend to a region on a top surface ILD1a of the first lower insulating layer ILD1.

In an embodiment, a top surface 12a of the second conductive line 12 is located at a height that is higher than the top surfaces 11a and 13a of the first and second conductive lines 11 and 13, when measured in a third direction D3 from the top surface 10a of the first substrate 10. For example, the top surface 12a may be located at a height that is higher than the top surfaces 11a and 13a with respect to the top surface 10a of the first substrate 10. The third direction D3 may be perpendicular to the top surface 10a of the first substrate 10. In an embodiment, the top surfaces 11a and 13a of the first and third conductive lines 11 and 13 are located at the same height. For example, the top surfaces 11a and 13a of the first and third conductive lines 11 and 13 may be located at the same height, when measured from the top surface 10a of the first substrate 10.

The first to third conductive lines 11, 12, and 13 and the first pattern insulating layer 20 may be referred to as a first interconnection layer M1.

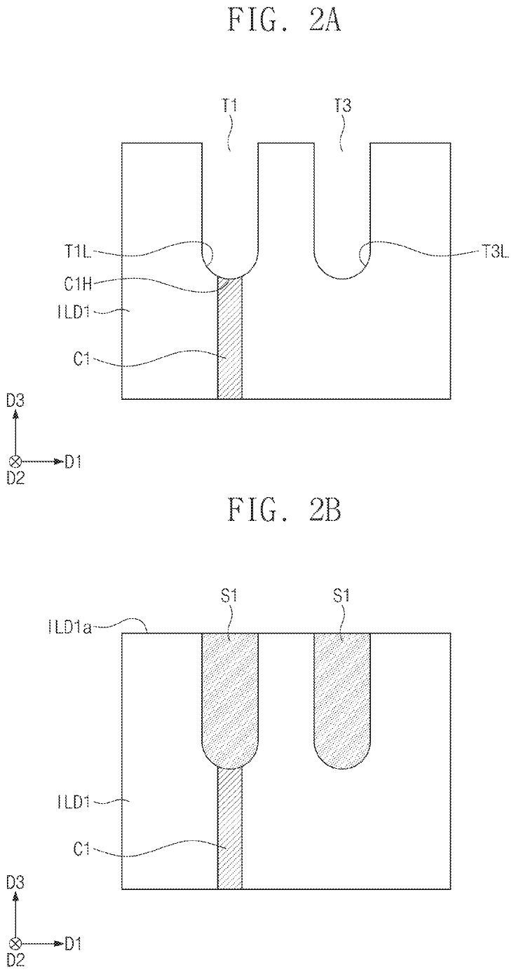

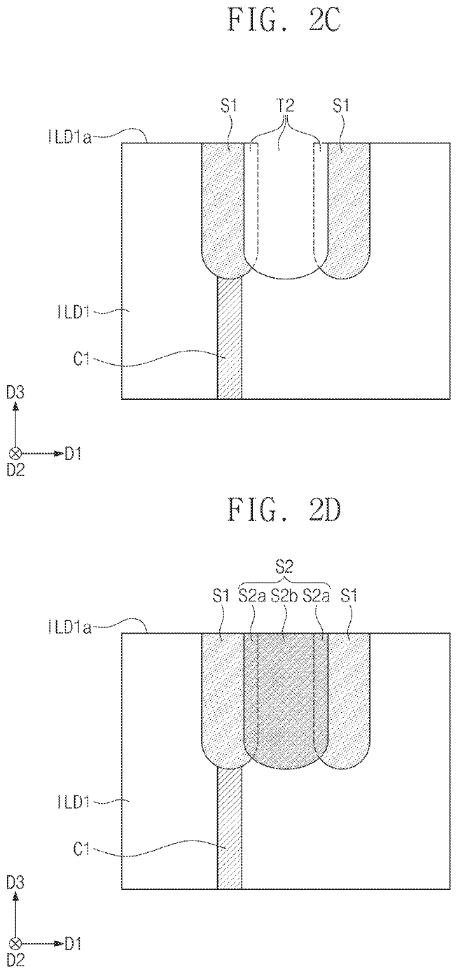

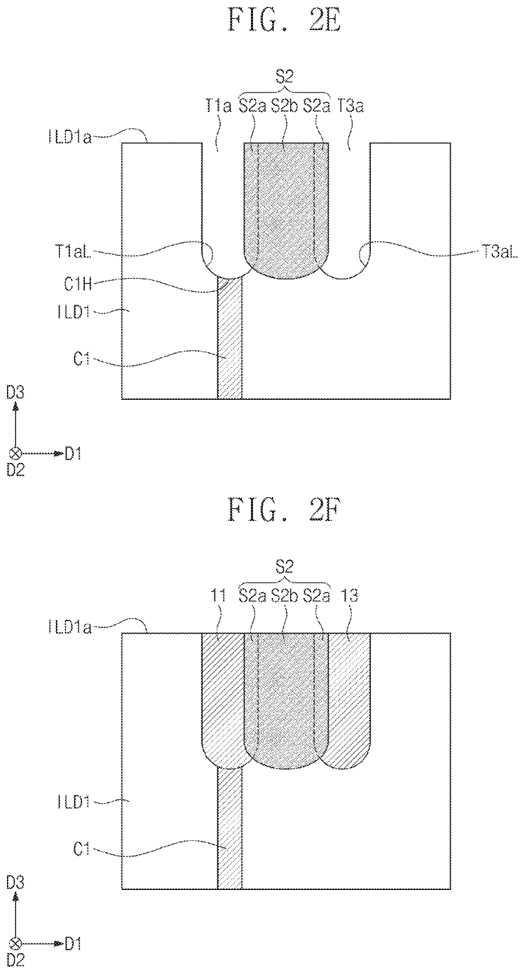

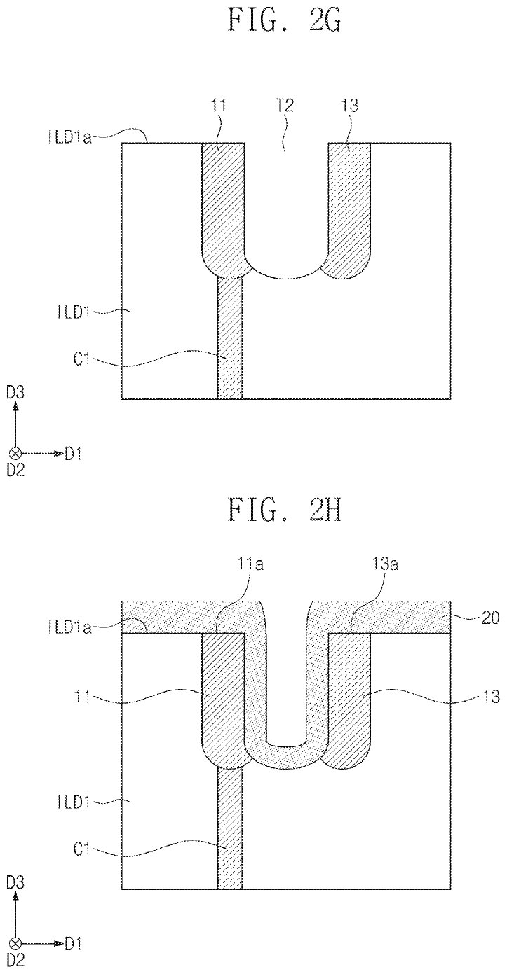

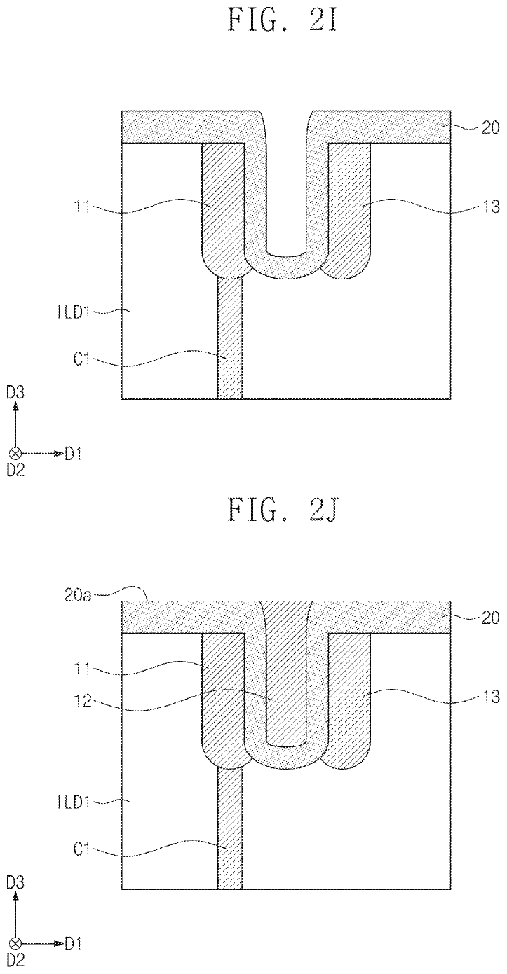

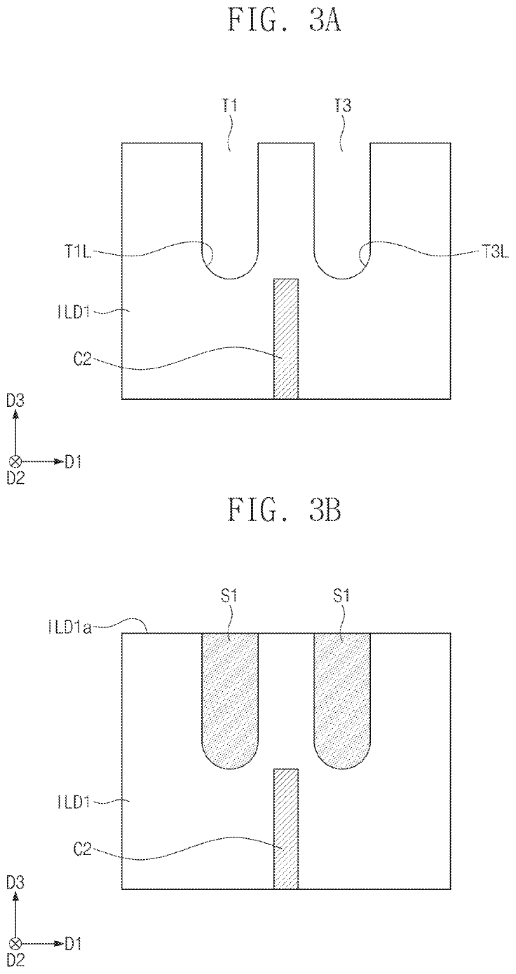

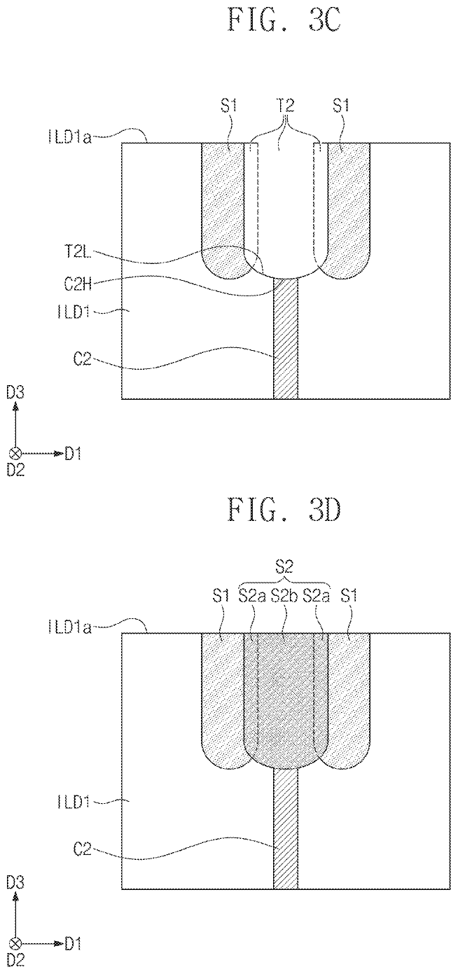

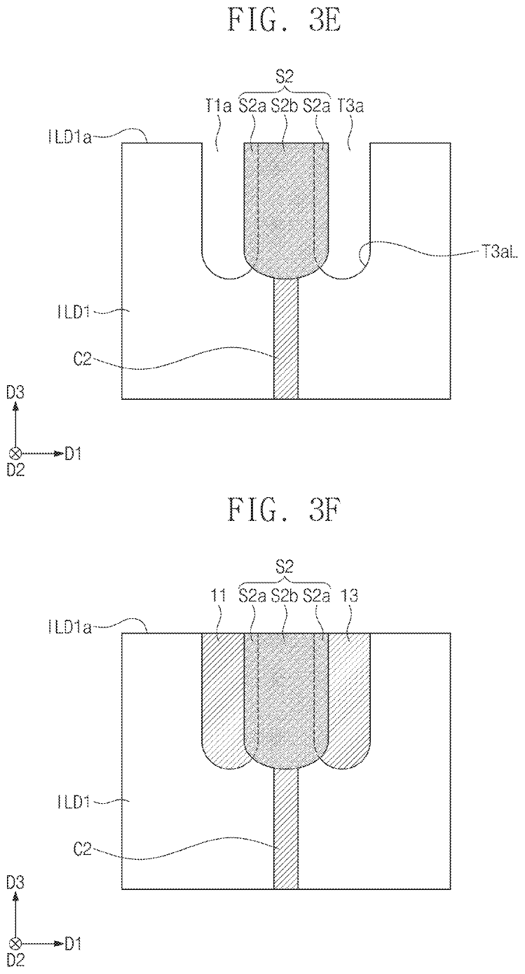

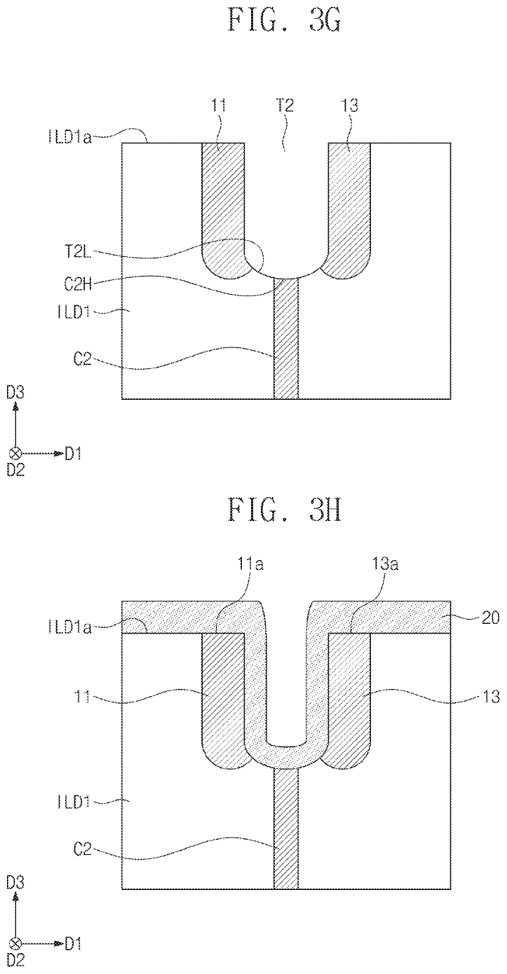

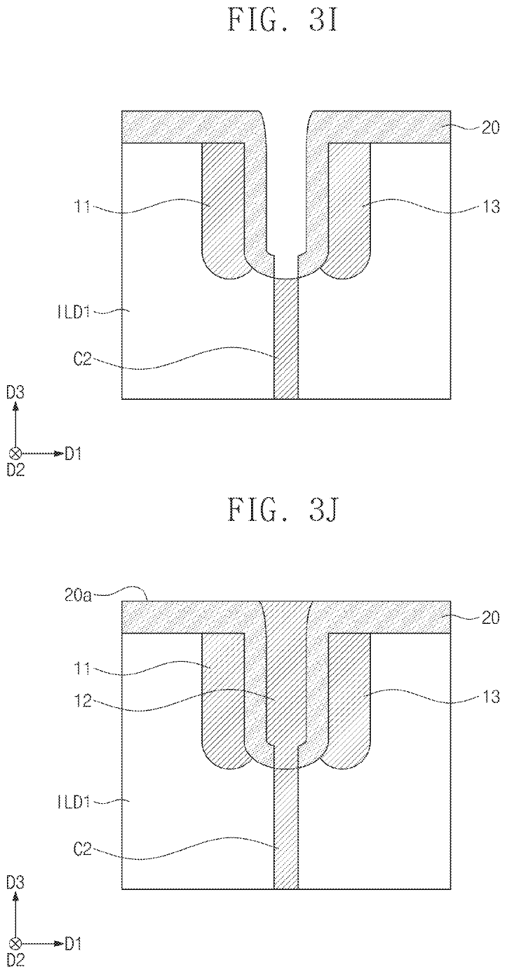

FIGS. 2A to 2J are sectional views, which are taken along the line I-I′ of FIG. 1A to illustrate a method of fabricating a semiconductor device, according to an embodiment of the inventive concept. FIGS. 3A to 3J are sectional views, which are taken along the line II-II′ of FIG. 1A to illustrate a method of fabricating a semiconductor device, according to an embodiment of the inventive concept. To simplify the drawings, the first substrate 10 and the transistor of FIG. 1A are not illustrated in FIGS. 2A to 2J and FIGS. 3A to 3J. In the following description, a method of fabricating a semiconductor memory device, according to an embodiment of the inventive concept, will be described in more detail with reference to FIGS. 1A to 1C, 2A to 2J, and 3A to 3J.

First, referring back to FIGS. 1B to 1D, the device isolation layer 14 may be formed in the first substrate 10 to define the active region AR. The gate structure GS and the source/drain regions 15 may be formed on the active region AR, and the first lower insulating layer ILD1 may be formed on the first substrate 10 to cover the gate structure GS and the source/drain regions 15. The first lower insulating layer ILD1 may be formed by a layer-forming method (e.g., chemical vapor deposition (CVD) and physical vapor deposition (PVD) methods). The first to the third contacts C1, C2, and C3, which are electrically and respectively connected to the gate structure GS and the source/drain regions 15, may be formed in the first lower insulating layer ILD1. The first to third contacts C1, C2, and C3 may be formed to penetrate the first lower insulating layer ILD1 and may be electrically connected to the gate structure GS and the source/drain regions 15.

Referring to FIGS. 2A and 3A, a first interconnection trench T1 and a third interconnection trench T3 are formed in the first lower insulating layer ILD1. For example, portions of the first lower insulating layer ILD1 are removed to form the first interconnection trench T1 and a third interconnection trench T3. In an embodiment, the formation of the first and third interconnection trenches T1 and T3 may include forming a first mask pattern on the first lower insulating layer ILD1 and anisotropically etching the first lower insulating layer ILD1 using the first mask pattern as an etch mask. The first interconnection trench T1 may have a bottom surface T1L exposing a top surface C1H of the first contact C1. Although not shown, the third interconnection trench T3 may have a bottom surface T3L exposing a top surface of the third contact C3. The first and third interconnection trenches T1 and T3 may be formed to be spaced apart from each other in the first direction D1 parallel to the top surface 10a of the first substrate 10 and may extend in the second direction D2.

Referring to FIGS. 2B and 3B, the first and third interconnection trenches T1 and T3 are filled with first sacrificial patterns S1, respectively. In an embodiment, the formation of the first sacrificial patterns S1 may include forming a first interconnection sacrificial layer on the first lower insulating layer ILD1 to fill the first and third interconnection trenches T1 and T3 and planarizing the first interconnection sacrificial layer to expose the top surface ILD1a of the first lower insulating layer ILD1. For example, the first interconnection sacrificial layer may be used to fill the first and third interconnection trenches T1 and T3 and then planarized to form the first sacrificial patterns S1. The first interconnection sacrificial layer may be formed using a layer-forming method (e.g., a chemical vapor deposition (CVD) method, a physical vapor deposition (PVD) method, or an atomic layer deposition (ALD) method). The planarization of the first interconnection sacrificial layer may be performed using a chemical mechanical polishing (CMP) process or an etch-back process. As a result of the planarization process, the first sacrificial patterns S1 may be locally formed in the first and third interconnection trenches T1 and T3. The first sacrificial patterns S1 may be formed of or include at least one of silicon (e.g., single- or poly-crystalline silicon), silicon carbide (SiC), or silicon nitride.

Referring to FIGS. 2C and 3C, a second interconnection trench T2 may be formed in the first lower insulating layer ILD1. For example, a portion of the first lower insulating layer ILD1 between the first sacrificial patterns S1 may be removed to form the second interconnection trench T2. The formation of the second interconnection trench T2 may include forming a second mask pattern on the first lower insulating layer ILD1 and anisotropically etching the first lower insulating layer ILD1 between the first sacrificial patterns S1 using the second mask pattern as an etch mask. In the formation of the second interconnection trench T2, the anisotropic etching process may be performed to further etch a portion of each of the first sacrificial patterns S1. For example, a right portion of the leftmost first sacrificial pattern S1 may be removed and a left portion of the rightmost first sacrificial pattern S1 may be removed.

The second interconnection trench T2 may be formed to penetrate a portion of each of the first sacrificial patterns S1 and the first lower insulating layer ILD1 between the first sacrificial patterns S1. The second interconnection trench T2 may have a bottom surface T2L exposing a top surface C2H of the second contact C2.

Referring to FIGS. 2D and 3D, the second interconnection trench T2 is filled with a second sacrificial pattern S2. In an embodiment, the formation of the second sacrificial pattern S2 may include forming a second interconnection sacrificial layer on the first lower insulating layer ILD1 to fill the second interconnection trench T2 and planarizing the second interconnection sacrificial layer to expose the top surface ILD1a of the first lower insulating layer ILD1. For example, the second interconnection trench T2 is filled with the second interconnection sacrificial layer and the second interconnection sacrificial layer is planarized to form the second sacrificial pattern S2. The second interconnection sacrificial layer may be formed using a layer-forming method (e.g., a chemical vapor deposition (CVD) method, a physical vapor deposition (PVD) method, or an atomic layer deposition (ALD) method). The planarization of the second interconnection sacrificial layer may be performed using a chemical mechanical polishing (CMP) process or an etch-back process. As a result of the planarization process, the second sacrificial pattern S2 may be locally formed in the second interconnection trench T2. The second sacrificial pattern S2 may include sidewall portions S2a and a center portion S2b between the sidewall portions S2a. The sidewall portions S2a of the second sacrificial pattern S2 may be located adjacent to the first sacrificial patterns S1, respectively. The second sacrificial pattern S2 may be formed of or include a material having a high etch selectivity with respect to the first sacrificial pattern S1. For example, the second sacrificial pattern S2 may be formed of or include a material, which is chosen from the group consisting of silicon (e.g., single- or poly-crystalline silicon), silicon carbide (SiC), or silicon nitride and is different from the first sacrificial patterns S1.

Referring to FIGS. 2E and 3E, the first sacrificial patterns S1 are removed to expose a portion T1a of the first interconnection trench T1 and a portion T3a of the third interconnection trench T3. The first sacrificial patterns S1 may be removed by an etching process. For example, the first sacrificial patterns S1 may be removed by a wet etching process using an etching solution. Due to the etch selectivity with respect to the first sacrificial pattern S1, the second sacrificial pattern S2 may not be removed during the etching process. The portion T1a of the first interconnection trench T1 may have a bottom surface T1aL exposing the top surface C1H of the first contact C1. In an embodiment, a width of the portion T1a of the first interconnection trench T1 in the first direction D1 is smaller than a width of the first interconnection trench T1 in the first direction D1. Although not shown, the portion T3a of the third interconnection trench T3 may have a bottom surface T3aL exposing a top surface of the third contact C3. In an embodiment, a width of the portion T3a of the third interconnection trench T3 in the first direction D1 is smaller than a width of the third interconnection trench T3 in the first direction D1. One of the sidewall portions S2a of the second sacrificial pattern S2 may fill a remaining portion of the first interconnection trench T1, and another one of the sidewall portions S2a of the second sacrificial pattern S2 may fill a remaining portion of the third interconnection trench T3.

Referring to FIGS. 2F and 3F, the first conductive line 11 is formed in the portion T1a of the first interconnection trench T1. The third conductive line 13 is formed in the portion T3a of the third interconnection trench T3. For example, the portion T1a may be filled with the first conductive line 11 and the portion T3a may be filled with the third conductive line 13. The formation of the first and third conductive lines 11 and 13 may include depositing a metal layer on the first lower insulating layer ILD1 to fill the portion T1a of the first interconnection trench T1 and the portion T3a of the third interconnection trench T3 and planarizing the metal layer to expose the top surface ILD1a of the first lower insulating layer ILD1. For example, the portions T1a and T3a may be filled with the metal layer and the metal layer may be planarized to form the conductive lines 11 and 13. A bottom surface of the first conductive line 11 may be in contact with the first contact C1. Although not shown, a bottom surface of the third conductive line 13 may be in contact with the third contact C3. In an embodiment, the top surfaces 11a and 13a of the first and third conductive lines 11 and 13 are located at the same height. For example, the top surfaces 11a and 13a of the first and third conductive lines 11 and 13 may be located at the same height when measured from the top surface 10a of the first substrate 10.

Referring to FIGS. 2G and 3G, the second sacrificial pattern S2 is removed to expose the second interconnection trench T2. The second sacrificial pattern S2 may be removed by an etching process. Dor example, the second sacrificial pattern S2 may be removed by a wet etching process using etching solution. The second interconnection trench T2 may be formed to have the bottom surface T2L exposing the top surface C2H of the second contact C2.

Referring to FIGS. 2H and 3H, the first pattern insulating layer 20 is formed to fill a portion of the second interconnection trench T2. The first pattern insulating layer 20 may be formed using a layer-forming method having a good step coverage property, such as a chemical vapor deposition (CVD) method, a physical vapor deposition (PVD) method, or an atomic layer deposition (ALD) method. The first pattern insulating layer 20 may be formed to conformally cover an inner side surface and a bottom surface of the second interconnection trench T2. For example, the thickness of a part of the first pattern insulating layer 20 covering the inner side surface and the bottom surface may be uniform. The first pattern insulating layer 20 may be exposed to regions on the top surfaces 11a and 13a of the first and third conductive lines 11 and 13 and the top surface ILD1a of the first lower insulating layer ILD1. The first pattern insulating layer 20 may be formed of or include at least one of silicon oxide, silicon nitride, silicon oxynitride, and/or low-k dielectric materials.

Referring to FIGS. 2I and 3I, a portion of the first pattern insulating layer 20, which is disposed on the bottom surface T2L of the second interconnection trench T2, may be removed to expose the second contact C2. The portion of the first pattern insulating layer 20 may be removed by an anisotropic etching process.

Referring to FIGS. 2J and 3J, the second conductive line 12 may be formed to fill a remaining portion of the second interconnection trench T2. As shown in FIG. 3J, a bottom surface of the second conductive line 12 may be in contact with the second contact C2. The formation of the second conductive line 12 may include depositing a conductive layer on the first pattern insulating layer 20 to fill the remaining portion of the second interconnection trench T2 and planarizing the conductive layer to expose a top surface 20a of the first pattern insulating layer 20.

The first pattern insulating layer 20 may be interposed between the first and second conductive lines 11 and 12 and between the second and third conductive lines 12 and 13. Referring to FIG. 2J, the first pattern insulating layer 20 may extend along the bottom surface of the second conductive line 12. Referring to FIG. 3J, the second conductive line 12 may be formed to penetrate a portion of the first pattern insulating layer 20 to be connected to the second contact C2. Referring back to FIGS. 1B to 1D, in an embodiment, the top surface 12a of the second conductive line 12 is formed at a height, which is higher than the top surfaces 11a and 13a of the first and third conductive lines 11 and 13, when measured in in the third direction D3 from the top surface 10a of the first substrate 10. For example, the top surface 12a may be formed at a height, which is higher than the top surfaces 11a and 13a with respect to the top surface 10a of the first substrate 10.

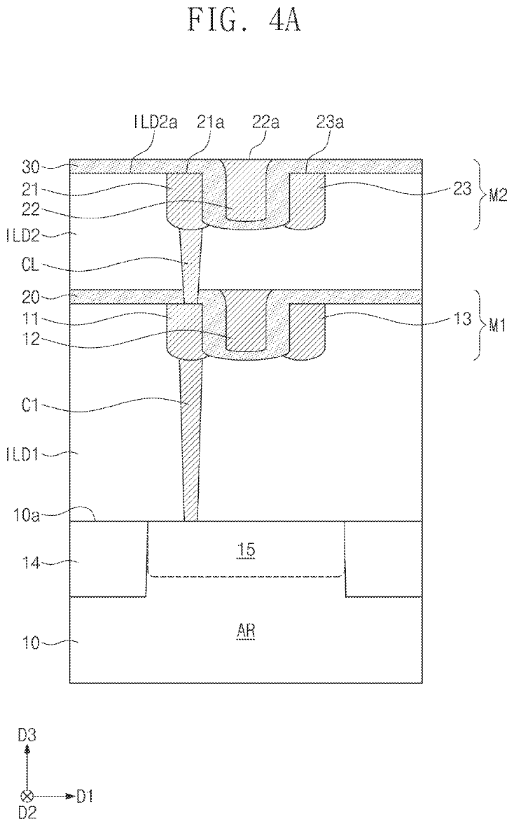

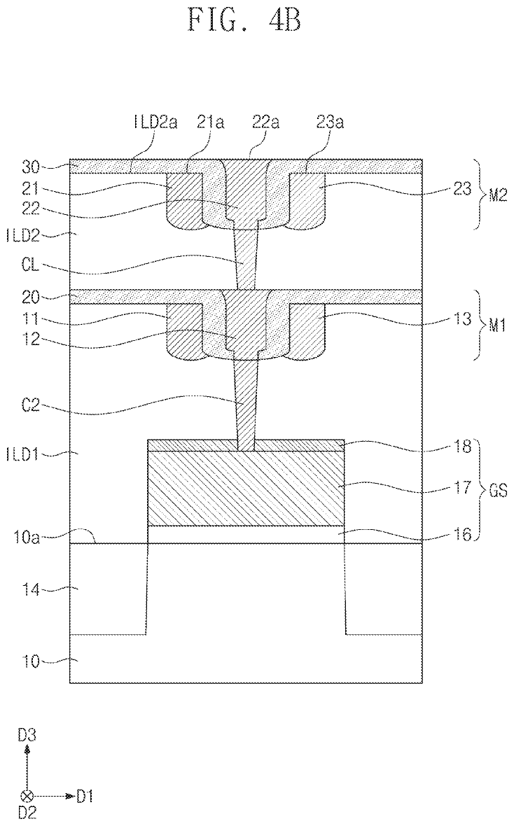

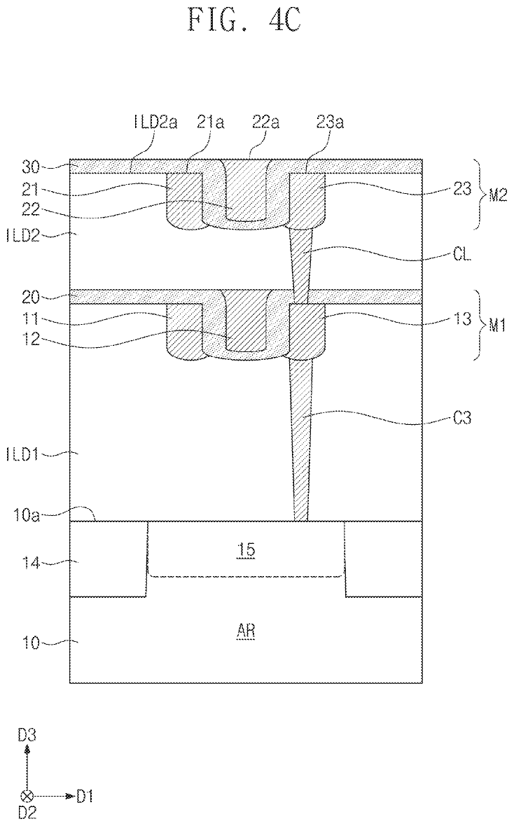

FIGS. 4A to 4C are sectional views, which are taken along the lines I-I′, II-II′, and III-III′ of FIG. 1A to illustrate a semiconductor device according to an embodiment of the inventive concept. In the following description, an element previously described with reference to FIGS. 1A to 1D, 2A to 2J, and 3A to 3J may be identified by the same reference number without repeating an overlapping description thereof, for concise description.

Referring to FIGS. 4A to 4C, a second lower insulating layer ILD2 is disposed on the first interconnection layer M1. Upper contacts CL, which are respectively connected to the conductive lines 11, 12, and 13 of the first interconnection layer M1, may be disposed in the second lower insulating layer ILD2.

Each of the upper contacts CL may be formed to penetrate a portion of the first pattern insulating layer 20 to be connected to a corresponding one of the first, and third conductive lines 11, and 13 of the first interconnection layer M1. For example, a first one of the upper contacts CL penetrates the first pattern insulating layer 20 to contact the first conductive line 11 in FIG. 4A, and a third one of the upper contacts CL penetrates the first pattern insulating layer 20 to contact the third conductive line 13 in FIG. 4C. In addition, one of the upper contacts CL may be connected to the second conductive line 12 in FIG. 4B.

A fourth conductive line 21, a fifth conductive line 22, and a sixth conductive line 23, which are respectively connected to the upper contacts CL, are disposed in the second lower insulating layer ILD2. The fourth conductive line 21, the fifth conductive line 22, and the sixth conductive line 23 may be provided to cross the gate structure GS, but the inventive concept is not limited to this example. In an embodiment, the fourth conductive line 21, the fifth conductive line 22, and the sixth conductive line 23 are spaced apart from each other in the first direction D1 and may extend in the second direction D2, but the inventive concept is not limited to this example.

The second lower insulating layer ILD2 may be formed of or include at least one of silicon oxide, silicon nitride, silicon oxynitride, and/or low-k dielectric materials. The upper contacts CL and the fourth to sixth conductive lines 21, 22, and 23 may be formed of or include at least one of metallic materials (e.g., tungsten, titanium, and tantalum) and/or conductive metal nitride materials (e.g., titanium nitride, tantalum nitride, and tungsten nitride).

A second pattern insulating layer 30 is interposed between the fourth conductive line 21 and the fifth conductive line 22 and between the fifth conductive line 22 and the sixth conductive line 23. The second pattern insulating layer 30 may extend along a bottom surface of the fifth conductive line 22. The fifth conductive line 22 may be formed to penetrate the second pattern insulating layer 30 to be connected to one of the upper contacts CL. The second pattern insulating layer 30 may extend to regions on top surfaces 21a and 23a of the fourth and sixth conductive lines 21 and 23 and may further extend to a region on a top surface ILD2a of the second lower insulating layer ILD2.

In an embodiment, a top surface 22a of the fifth conductive line 22 is located at a height higher than the top surfaces 21a and 23a of the fourth and sixth conductive lines 21 and 23, when measured in the third direction D3 from the top surface 10a of the first substrate 10. For example, the top surface 22a may be located at a height higher than the top surfaces 21a and 23a, with respect to the top surface 10a of the first substrate 10. In an embodiment, the top surfaces 21a and 23a of the fourth and sixth conductive lines 21 and 23 are located at the same height. For example, the top surfaces 21a and 23a may be located at the same height, when measured from the top surface 10a of the first substrate 10.

The fourth to sixth conductive lines 21, 22, and 23 and the second pattern insulating layer 30 may be referred to as a second interconnection layer M2.

The second lower insulating layer ILD2, the upper contacts CL, and the second interconnection layer M2 of FIGS. 4A to 4C may be formed by substantially the same method as the method of forming the first lower insulating layer ILD1, the first to third contacts C1, C2, and C3, and the first interconnection layer M1, described with reference to FIGS. 2A to 2J and 3A to 3J.

One of the upper contacts CL may be formed to penetrate a portion of the first pattern insulating layer 20 to be connected to the first conductive line 11, and another one of the upper contacts CL may be formed to penetrate another portion of the first pattern insulating layer 20 to be connected to the third conductive line 13.

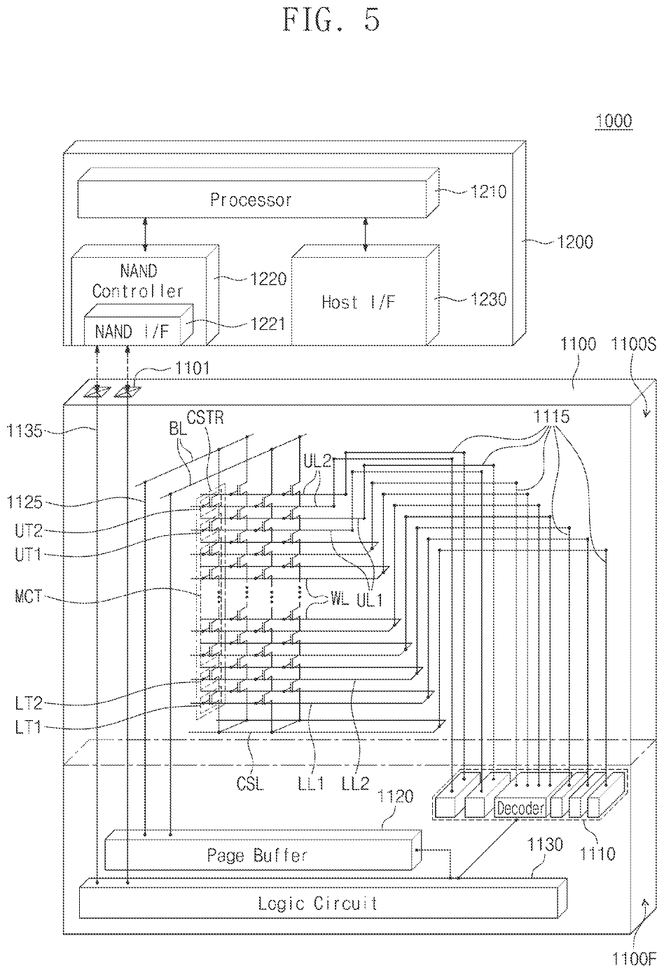

FIG. 5 is a diagram schematically illustrating an electronic system including a three-dimensional semiconductor memory device, according to an embodiment of the inventive concept.

Referring to FIG. 5, an electronic system 1000 may include a three-dimensional semiconductor memory device 1100 and a controller 1200 (e.g., a controller circuit), which is electrically connected to the three-dimensional semiconductor memory device 1100. The electronic system 1000 may be a storage device including one or more three-dimensional semiconductor memory devices 1100 or an electronic device including the storage device. For example, the electronic system 1000 may be a solid state drive (SSD) device, a universal serial bus (USB), a computing system, a medical system, or a communication system, in which at least one three-dimensional semiconductor memory devices 1100 is provided.

The three-dimensional semiconductor memory device 1100 may be a nonvolatile memory device (e.g., a three-dimensional NAND FLASH memory device to be described below). The three-dimensional semiconductor memory device 1100 may include a first region 1100F and a second region 1100S on the first region 1100F. For example, the first region 1100F may be disposed near the second region 1100S. The first region 1100F may be a peripheral circuit region, which includes a decoder circuit 1110, a page buffer 1120, and a logic circuit 1130. The second region 1100S may be a memory cell region, which includes a bit line BL, a common source line CSL, word lines WL, first lines LL1 and LL2, second lines UL1 and UL2, and memory cell strings CSTR between the bit line BL and the common source line CSL.

In the second region 1100S, each of the memory cell strings CSTR may include first transistors LT1 and LT2 adjacent to the common source line CSL, second transistors UT1 and UT2 adjacent to the bit line BL, and a plurality of memory cell transistors MCT disposed between the first transistors LT1 and LT2 and the second transistors UT1 and UT2. The number of the first transistors LT1 and LT2 and the number of the second transistors UT1 and UT2 may be variously changed, according to embodiments.

In an embodiment, the first transistors LT1 and LT2 may include a ground selection transistor, and the second transistors UT1 and UT2 may include a string selection transistor. The first lines LL1 and LL2 may serve as gate electrodes of the first transistors LT1 and LT2, respectively. The word lines WL may serve as gate electrodes of the memory cell transistors MCT. The second lines UL1 and UL2 may serve as gate electrodes of the second transistors UT1 and UT2, respectively.

In an embodiment, the first transistors LT1 and LT2 may include a first erase control transistor LT1 and a ground selection transistor LT2, which are connected in series. The second transistors UT1 and UT2 may include a string selection transistor UT1 and a second erase control transistor UT2, which are connected in series. At least one of the first and second erase control transistors LT1 and UT2 may be used for an erase operation of erasing data, which are stored in the memory cell transistors MCT, using a gate-induced drain leakage (GIDL) phenomenon.

The common source line CSL, the first lines LL1 and LL2, the word lines WL, and the second lines UL1 and UL2 may be electrically connected to the decoder circuit 1110 through first interconnection lines 1115, which extend from the first region 1100F to the second region 1100S. The bit line BL may be electrically connected to the page buffer 1120 through second interconnection lines 1125, which extend from the first region 1100F to the second region 1100S.

In the first region 1100F, the decoder circuit 1110 and the page buffer 1120 may be configured to perform a control operation, which is performed on at least one selected one of the memory cell transistors MCT. The decoder circuit 1110 and the page buffer 1120 may be controlled by the logic circuit 1130. The three-dimensional semiconductor memory device 1100 may communicate with the controller 1200 through an input/output pad 1101, which is electrically connected to the logic circuit 1130. The input/output pad 1101 may be electrically connected to the logic circuit 1130 through an input/output interconnection line 1135, which is extended from the first region 1100F to the second region 1100S.

The controller 1200 may include a processor 1210, a NAND controller 1220, and a host interface 1230. For example, the electronic system 1000 may include a plurality of three-dimensional semiconductor memory devices 1100, and in this case, the controller 1200 may control the three-dimensional semiconductor memory devices 1100.

The processor 1210 may control overall operations of the electronic system 1000 including the controller 1200. Based on a specific firmware, the processor 1210 may execute operations of controlling the NAND controller 1220 and accessing the three-dimensional semiconductor memory device 1100. The NAND controller 1220 may include a NAND interface 1221, which is used for communication with the three-dimensional semiconductor memory device 1100. The NAND interface 1221 (e.g., an interface circuit) may be used to transmit and receive control commands, which are used to control the three-dimensional semiconductor memory device 1100, data, which will be written in or read from the memory cell transistors MCT of the three-dimensional semiconductor memory device 1100, and so forth. The host interface 1230 may be configured to allow for communication between the electronic system 1000 and an external host. If a control command is received from an external host through the host interface 1230 (e.g., an interface circuit), the processor 1210 may control the three-dimensional semiconductor memory device 1100 in response to the control command.

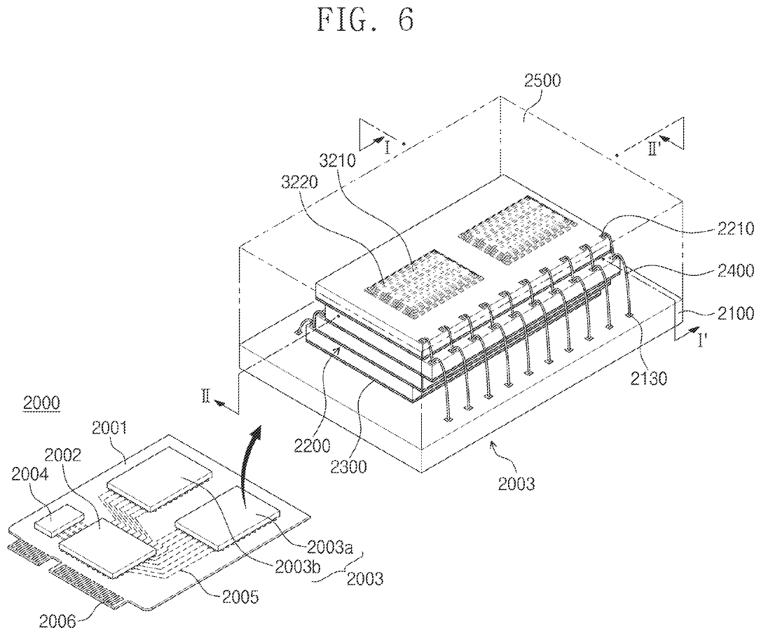

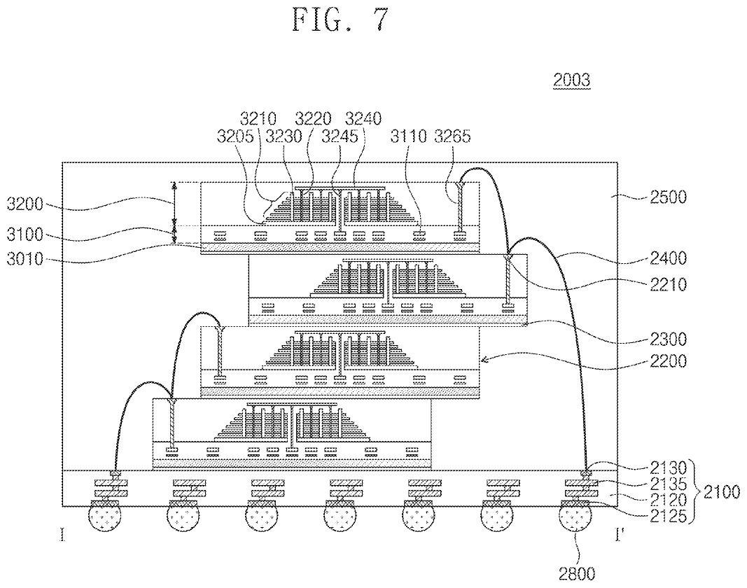

FIG. 6 is a perspective view schematically illustrating an electronic system including a three-dimensional semiconductor memory device, according to an embodiment of the inventive concept.

Referring to FIG. 6, an electronic system 2000 may include a main substrate 2001 and a controller 2002 (e.g., a controller circuit), at least one semiconductor package 2003, and a DRAM 2004, which are mounted on the main substrate 2001. The semiconductor package 2003 and the DRAM 2004 may be connected to the controller 2002 and to each other by interconnection patterns 2005 (e.g., lines, wires, etc.), which are located in the main substrate 2001.

The main substrate 2001 may include a connector 2006, which includes a plurality of pins coupled to an external host. In the connector 2006, the number and arrangement of the pins may depend on a communication interface between the electronic system 2000 and the external host. In an embodiment, the electronic system 2000 may communicate with the external host, in accordance with one of a plurality of interfaces, such as universal serial bus (USB), peripheral component interconnect express (PCI-Express), serial advanced technology attachment (SATA), universal flash storage (UFS) M-PHY, or the like. In an embodiment, the electronic system 2000 may be driven by electric power, which is supplied from the external host through the connector 2006. The electronic system 2000 may further include a power management integrated circuit (PMIC), which is used to distribute a power supplied from the external host to the controller 2002 and the semiconductor package 2003.

The controller 2002 may be configured to control performing a writing or reading operation on the semiconductor package 2003 and to increase an operation speed of the electronic system 2000.

The DRAM 2004 may be a buffer memory, which relieves technical difficulties caused by a difference in speed between the semiconductor package 2003, which serves as a data storage device, and an external host. In an embodiment, the DRAM 2004 in the electronic system 2000 may serve as a cache memory and may provide a storage space, which data are temporarily stored, during various control operations performed on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 respectively disposed on bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be a printed circuit board including package upper pads 2130. Each of the semiconductor chips 2200 may include input/output pads 2210. Each of the input/output pads 2210 may correspond to the input/output pad 1101 of FIG. 5. Each of the semiconductor chips 2200 may include gate stacks 3210 and vertical channel structures 3220. Each of the semiconductor chips 2200 may include a three-dimensional semiconductor memory device, which will be described below.

In an embodiment, the connection structure 2400 may be a bonding wire electrically connecting the input/output pads 2210 to the package upper pads 2130. In each of the first and second semiconductor packages 2003a and 2003b, the semiconductor chips 2200 may be electrically connected to each other in a bonding wire manner and may be electrically connected to the package upper pads 2130 of the package substrate 2100. In an embodiment, the semiconductor chips 2200 in each of the first and second semiconductor packages 2003a and 2003b is electrically connected to each other by through silicon vias (TSVs), and not by the connection structure 2400 provided in the form of bonding wires.

In an embodiment, the controller 2002 and the semiconductor chips 2200 are included in a single package. For example, the controller 2002 and the semiconductor chips 2200 may be mounted on an interposer substrate, which is formed independent of the main substrate 2001, and may be connected to each other through interconnection lines, which are disposed in the interposer substrate.

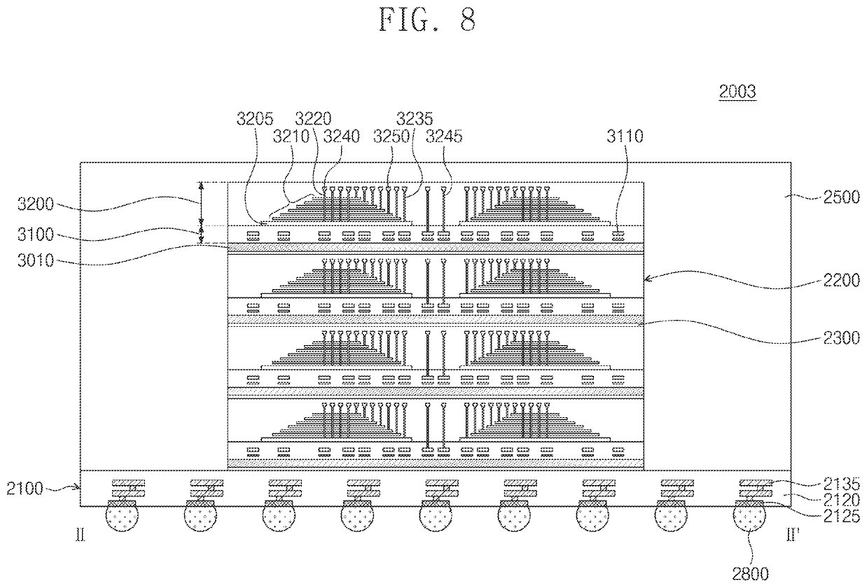

FIGS. 7 and 8 are sectional views, which are respectively taken along lines I-I′ and II-II′ of FIG. 6 to illustrate a semiconductor package including a three-dimensional semiconductor memory device, according to an embodiment of the inventive concept.

Referring to FIGS. 7 and 8, the semiconductor package 2003 may include the package substrate 2100, a plurality of semiconductor chips disposed on the package substrate 2100, and the molding layer 2500 covering the package substrate 2100 and the semiconductor chips.

The package substrate 2100 may include a package substrate body portion 2120, the package upper pads 2130 disposed on a top surface of the package substrate body portion 2120, lower pads 2125 disposed on or exposed through a bottom surface of the package substrate body portion 2120, and internal lines 2135 provided in the package substrate body portion 2120 to electrically connect the upper pads 2130 to the lower pads 2125. The package upper pads 2130 may be electrically connected to the connection structures 2400. The lower pads 2125 may be connected to the interconnection patterns 2005 of the main substrate 2001 of the electronic system 2000 shown in FIG. 6 through conductive connecting portions 2800.

Each of the semiconductor chips 2200 may include a semiconductor substrate 3010 and a first structure 3100 and a second structure 3200, which are sequentially stacked on the semiconductor substrate 3010. The first structure 3100 may include a peripheral circuit region, in which peripheral lines 3110 are provided. The second structure 3200 may include a common source line 3205, the gate stack 3210 on the common source line 3205, the vertical channel structures 3220 and separation structures 3230 penetrating the gate stack 3210, bit lines 3240 electrically connected to the vertical channel structures 3220, gate connection lines 3235 electrically connected to the word lines WL (e.g., see FIG. 5) of the gate stack 3210, and conductive lines 3250.

Each of the semiconductor chips 2200 may be electrically connected to the peripheral lines 3110 of the first structure 3100 and may include a penetration line 3245, which is extended into the second structure 3200. The penetration line 3245 may be provided to penetrate the gate stack 3210 and may be disposed outside the gate stack 3210. Each of the semiconductor chips 2200 may be electrically connected to the peripheral lines 3110 of the first structure 3100 and may further include an input/output connection line 3265, which is extended into the second structure 3200, and the input/output pad 2210, which is electrically connected to the input/output connection line 3265.

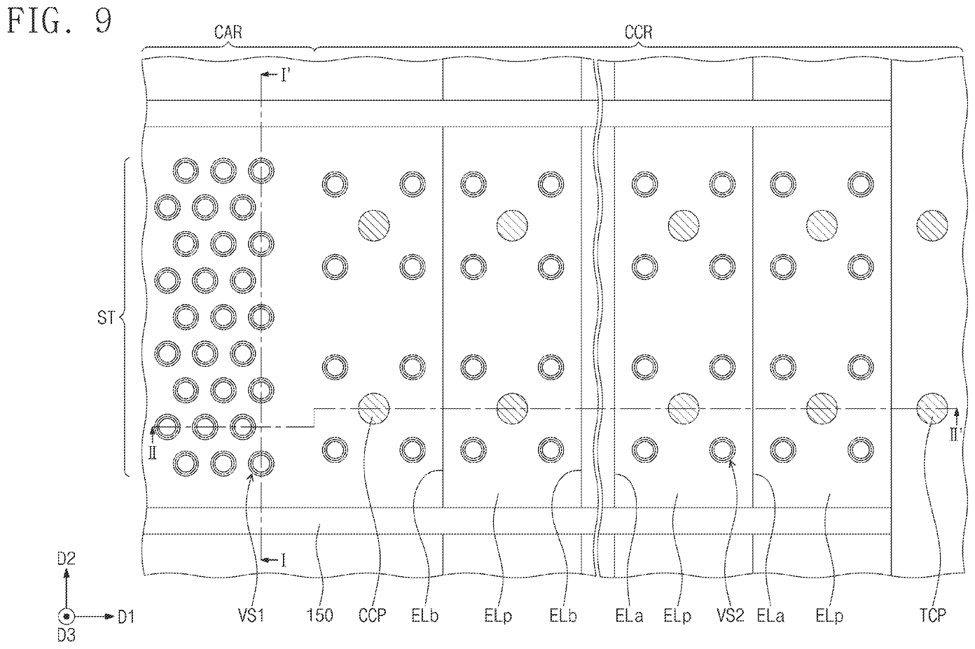

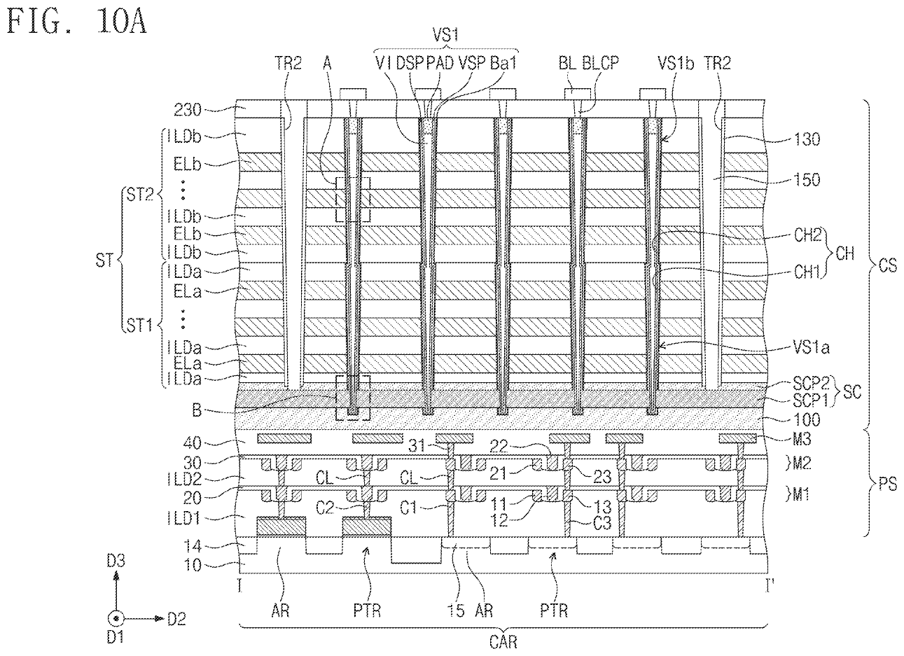

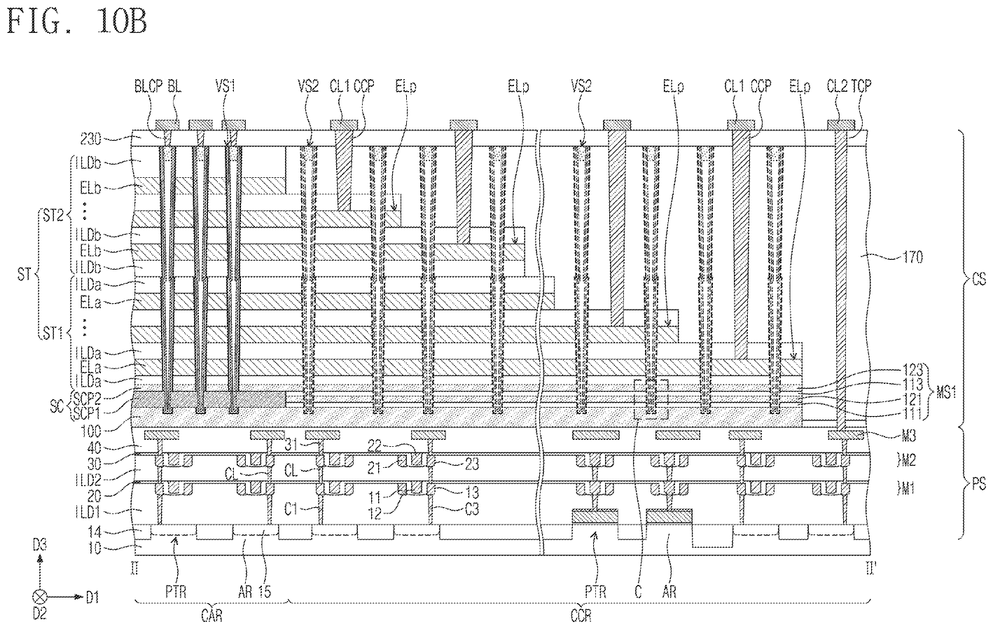

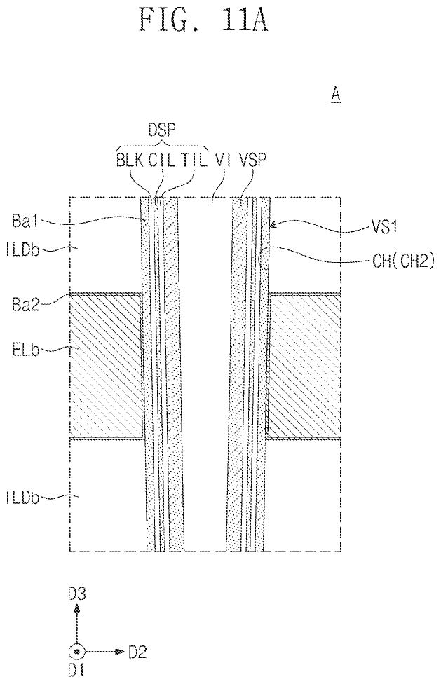

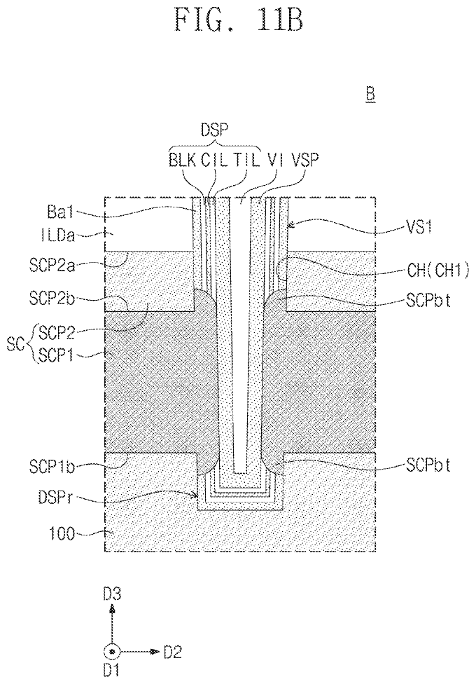

FIG. 9 is a plan view illustrating a three-dimensional semiconductor memory device according to an embodiment of the inventive concept. FIGS. 10A and 10B are sectional views, which are respectively taken along lines I-I′ and II-II′ of FIG. 9 to illustrate a three-dimensional semiconductor memory device according to an embodiment of the inventive concept.

Referring to FIGS. 9, 10A, and 10B, a three-dimensional semiconductor memory device may include a first substrate 10, a peripheral circuit structure PS on the first substrate 10, and a cell array structure CS on the peripheral circuit structure PS. The first substrate 10, the peripheral circuit structure PS, and the cell array structure CS may correspond to the semiconductor substrate 3010, the first structure 3100 on the semiconductor substrate 3010, and the second structure 3200 on the first structure 3100, respectively, which are illustrated in FIGS. 7 and 8.

The first substrate 10 including a cell array region CAR and a contact region CCR may be provided. The first substrate 10 may extend in two different directions (e.g., the first and second directions D1 and D2), and here, the first direction D1 may be directed from the cell array region CAR toward the contact region CCR. A top surface of the first substrate 10 may be perpendicular to the third direction D3, which is non-parallel to the first and second directions D1 and D2. For example, the first, second, and third directions D1, D2, and D3 may be orthogonal to each other.

When viewed in a plan view, the contact region CCR may extend from the cell array region CAR in the first direction D1 or an opposite direction of the first direction D1. The cell array region CAR may be a region, on which the vertical channel structures 3220 described with reference to FIGS. 7 and 8, the separation structures 3230, and the bit lines 3240 electrically connected to the vertical channel structures 3220 are provided. The contact region CCR may be a region, on which a stepwise structure including pad portions ELp to be described below is provided. Unlike that illustrated in the drawings, the contact region CCR may extend from the cell array region CAR in the second direction D2 or an opposite direction of the second direction D2.

In an embodiment, the first substrate 10 may be a silicon substrate, a silicon-germanium substrate, a germanium substrate, or a structure including a single-crystalline silicon substrate and a single crystalline epitaxial layer grown therefrom. The device isolation layer 14 may be located in the first substrate 10. The device isolation layer 14 may define an active region of the first substrate 10. The device isolation layer 14 may be formed of or include, for example, silicon oxide.

The peripheral circuit structure PS may be disposed on the first substrate 10. The peripheral circuit structure PS may include peripheral circuit transistors PTR, the first lower insulating layer ILD1, the second lower insulating layer ILD2, a first insulating layer 40, the first interconnection layer M1, the second interconnection layer M2, a third interconnection layer M3, first to third contacts C1, C2, and C3, the upper contacts CL, and peripheral contacts 31, which are disposed on the active region AR of the first substrate 10.

Each of the peripheral circuit transistors PTR may include the gate structure GS and the source/drain regions 15, which are disposed in the first substrate 10 and at both sides of the gate structure GS, as described previously with reference to FIGS. 1A to 1D.

The first lower insulating layer ILD1, the first to third contacts C1, C2, and C3, and the first interconnection layer M1 may be substantially the same as the first lower insulating layer ILD1, the first to third contacts C1, C2, and C3, and the first interconnection layer M1 described with reference to FIGS. 1A to 4C. The first interconnection layer M1 may include the first conductive line 11, the second conductive line 12, the third conductive line 13, and the first pattern insulating layer 20, as described previously with reference to FIGS. 1A to 4C.

The second lower insulating layer ILD2, the upper contacts CL, and the second interconnection layer M2 may be substantially the same as the second lower insulating layer ILD2, the upper contacts CL, and the second interconnection layer M2 described with reference to FIGS. 4A to 4C. The second interconnection layer M2 may include the fourth conductive line 21, the fifth conductive line 22, the sixth conductive line 23, and the second pattern insulating layer 30, as described previously with reference to FIGS. 4A to 4C.

The first insulating layer 40 may be disposed on the second interconnection layer M2. The peripheral contacts 31, which are respectively connected to the conductive lines 21, 22, and 23 of the second interconnection layer M2, may be disposed in the first insulating layer 40. The third interconnection layer M3 may be disposed in the first insulating layer 40.

The first to sixth conductive lines 11, 12, 13, 21, 22, and 23 and the third interconnection layer M3 may be electrically connected to the peripheral circuit transistors PTR through the first to third contacts C1, C2, and C3, the upper contacts CL, and the peripheral contacts 31. The peripheral circuit structure PS may correspond to the first region 1100F of FIG. 5. In an embodiment, the third interconnection layer M3 has the same or substantially the same structure as the first interconnection layer M1 or the second interconnection layer M2, but the inventive concept is not limited to this example.

The first to sixth conductive lines 11, 12, 13, 21, 22, and 23, the third interconnection layer M3, the first to third contacts C1, C2, and C3, the upper contacts CL, and the peripheral contacts 31 may be formed of or include at least one of conductive or metallic materials.

The first insulating layer 40 may have a multi-layered structure including a plurality of insulating layers. For example, the first insulating layer 40 may be formed of or include at least one of silicon oxide, silicon nitride, silicon oxynitride, and/or low-k dielectric materials.

The cell array structure CS may be disposed on the first insulating layer 40, and here, the cell array structure CS may include a second substrate 100 and a stack ST disposed on the second substrate 100. The second substrate 100 may extend in the first and second directions D1 and D2. In an embodiment, the second substrate 100 is not disposed on a portion of the contact region CCR. The second substrate 100 may be a semiconductor substrate including a semiconductor material. The second substrate 100 may be formed of or include at least one of silicon (Si), germanium (Ge), silicon germanium (SiGe), gallium arsenic (GaAs), indium gallium arsenic (InGaAs), or aluminum gallium arsenic (AlGaAs).

The stack ST may be disposed on the second substrate 100. The stack ST may extend from the cell array region CAR to the contact region CCR. The stack ST may correspond to the stacks 3210 of FIGS. 7 and 8. In an embodiment, a plurality of the stacks ST may be arranged in the second direction D2 and may be spaced apart from each other in the second direction D2 with a separation structure 150 interposed therebetween. For brevity's sake, just one stack ST will be described below, but the others of the stacks ST may also have substantially the same features as described below.

The stack ST may include interlayer insulating layers ILDa and ILDb and gate electrodes ELa and ELb, which are alternately stacked. The gate electrodes ELa and ELb may correspond to the word lines WL, the first lines LL1 and LL2, and the second lines UL1 and UL2 of FIG. 5.

More specifically, the stack ST may include a first stack ST1 disposed on the second substrate 100 and a second stack ST2 disposed on the first stack ST1. The first stack ST1 may include first interlayer insulating layers ILDa and first gate electrodes Ela, which are alternatively stacked, and the second stack ST2 may include second interlayer insulating layers ILDb and second gate electrodes ELb, which are alternatively stacked. The first and second gate electrodes ELa and ELb may have the same or substantially the same thickness in the third direction D3. Hereinafter, the term ‘thickness’ may be used to represent a length of an element in the third direction D3.

In an embodiment, for the first and second gate electrodes ELa and ELb, a length in the first direction D1 decreases with increasing distance from the second substrate 100 (i.e., with increasing distance in the third direction D3). That is, a length of each of the first and second gate electrodes ELa and ELb in the first direction D1 may be larger than a length of another electrode thereon in the first direction D1. The lowermost one of the first gate electrodes ELa of the first stack ST1 may have the largest length in the first direction D1, and the uppermost one of the second gate electrodes ELb of the second stack ST2 may have the smallest length in the first direction D1.

The first and second gate electrodes ELa and ELb may have the pad portions ELp, disposed on the contact region CCR. The pad portions ELp of the first and second gate electrodes ELa and ELb may be disposed at positions that are different from each other in horizontal and vertical directions. The pad portions ELp may form a stepwise structure in the first direction D1.

Due to the stepwise structure, each of the first and second stacks ST1 and ST2 may have a thickness decreasing with increasing distance from the outermost one of first vertical channel structures VS1 to be described below, and the side surfaces of the first and second gate electrodes ELa and ELb may be spaced apart from each other in the first direction D1 by a specific distance, when viewed in a plan view.

The first and second gate electrodes ELa and ELb may be formed of or include at least one of, for example, doped semiconductor materials (e.g., doped silicon and so forth), metallic materials (e.g., tungsten, copper, aluminum, and so forth), conductive metal nitrides (e.g., titanium nitride, tantalum nitride, and so forth), or transition metals (e.g., titanium, tantalum, and so forth). In an embodiment, the first and second gate electrodes ELa and ELb may be formed of or include tungsten.

The first and second interlayer insulating layers ILDa and ILDb may be disposed between the first and second gate electrodes ELa and ELb and each of them may have a side surface that is aligned to a side surface of a corresponding one of the first and second gate electrodes ELa and ELb, which is disposed thereunder and is in contact therewith. In other words, the first and second interlayer insulating layers ILDa and ILDb may be disposed such that a length in the first direction D1 decreases with increasing distance from the second substrate 100, similar to the first and second gate electrodes ELa and ELb.

The lowermost one of the second interlayer insulating layers ILDb may be in contact with the uppermost one of the first interlayer insulating layers ILDa. In an embodiment, a thickness of each of the first and second interlayer insulating layers ILDa and ILDb is smaller than a thickness of each of the first and second gate electrodes ELa and ELb. The lowermost one of the first interlayer insulating layers ILDa may be thinner than the others of the interlayer insulating layers ILDa and ILDb. For example, the uppermost one of the second interlayer insulating layers ILDb may be thicker than the others of the interlayer insulating layers ILDa and ILDb.

Except for the lowermost one of the first interlayer insulating layers ILDa and the uppermost one of the second interlayer insulating layers ILDb, the remaining ones of the interlayer insulating layers ILDa and ILDb may have substantially the same thickness. However, inventive concept is not limited to this example, and the thicknesses of the first and second interlayer insulating layers ILDa and ILDb may be variously changed depending on requirements for the semiconductor device.

The first and second interlayer insulating layers ILDa and ILDb may be formed of or include at least one of, for example, silicon oxide, silicon nitride, silicon oxynitride, and/or low-k dielectric materials. For example, the first and second interlayer insulating layers ILDa and ILDb may be formed of or include high density plasma (HDP) oxide or tetraethylorthosilicate (TEOS).

In an embodiment, a source structure SC is disposed between the second substrate 100 on the cell array region CAR and the lowermost one of the first interlayer insulating layers ILDa. The source structure SC may correspond to the common source line CSL of FIG. 5 and the common source line 3205 of FIGS. 7 and 8. The source structure SC may include a first source conductive pattern SCP1 and a second source conductive pattern SCP2, which are sequentially stacked on the second substrate 100. The second source conductive pattern SCP2 may be disposed between the first source conductive pattern SCP1 and the lowermost one of the first interlayer insulating layers ILDa. In an embodiment, a thickness of the first source conductive pattern SCP1 is larger than a thickness of the second source conductive pattern SCP2. The first and second source conductive patterns SCP1 and SCP2 may be formed of or include a semiconductor material (e.g., silicon) or a doped semiconductor material. In the case where the first and second source conductive patterns SCP1 and SCP2 include the doped semiconductor material, an impurity concentration of the first source conductive pattern SCP1 may be higher than an impurity concentration of the second source conductive pattern SCP2.

In an embodiment, the first source conductive pattern SCP1 of the source structure SC is disposed on only the cell array region CAR, and not on the contact region CCR. By contrast, the second source conductive pattern SCP2 of the source structure SC may extend from the cell array region CAR to the contact region CCR. The second source conductive pattern SCP2 disposed on the contact region CCR may be referred to as a second semiconductor layer 123.

A first mold structure MS1 may be disposed between the second substrate 100 on the contact region CCR and the lowermost one of the first interlayer insulating layers ILDa. The first mold structure MS1 may include a first buffer insulating layer 111, a first semiconductor layer 121, a second buffer insulating layer 113, and the second semiconductor layer 123, which are sequentially stacked on the second substrate 100.

The first semiconductor layer 121 may be disposed between the second substrate 100 and the second semiconductor layer 123. The first buffer insulating layer 111 may be disposed between the second substrate 100 and the first semiconductor layer 121, and the second buffer insulating layer 113 may be disposed between the first semiconductor layer 121 and the second semiconductor layer 123. In an embodiment, a bottom surface of the first buffer insulating layer 111 is coplanar or substantially coplanar with a bottom surface of the first source conductive pattern SCP1. In an embodiment, a top surface of the second buffer insulating layer 113 is coplanar or substantially coplanar with a top surface of the first source conductive pattern SCP1.

In an embodiment, the first and second buffer insulating layers 111 and 113 may be formed of or include silicon oxide. The first and second semiconductor layers 121 and 123 may be formed of or include a material having an etch selectivity with respect to a first barrier pattern Ba1. For example, the first and second semiconductor layers 121 and 123 may be formed of or include a semiconductor material (e.g., silicon).

The first vertical channel structures VS1 may be provided to penetrate the stack ST and the source structure SC on the cell array region CAR. The first vertical channel structures VS1 may be provided to penetrate at least a portion of the second substrate 100. In an embodiment, a bottom surface of each of the first vertical channel structures VS1 is located at a level lower than a top surface of the second substrate 100 and a bottom surface of the source structure SC. In other words, the first vertical channel structures VS1 may be in direct contact with the second substrate 100.

The first vertical channel structures VS1 may be arranged to form a zigzag shape in the first or second direction D1 or D2, when viewed in the plan view of FIG. 9. In an embodiment, the first vertical channel structures VS1 is not provided on the contact region CCR. The first vertical channel structures VS1 may correspond to the vertical channel structures 3220 of FIGS. 6 to 8. The first vertical channel structures VS1 may correspond to the channel regions of the first transistors LT1 and LT2, the memory cell transistors MCT, and the second transistors UT1 and UT2 of FIG. 5.

The first vertical channel structures VS1 may be provided in vertical channel holes CH penetrating the stack ST. Each of the vertical channel holes CH may include a first vertical channel hole CH1 penetrating the first stack ST1 and a second vertical channel hole CH2 penetrating the second stack ST2. The first and second vertical channel holes CH1 and CH2 of each of the vertical channel holes CH may be connected to each other in the third direction D3.

Each of the first vertical channel structures VS1 may include a first portion VS1a and a second portion VS1b. The first portion VS1a may be provided in the first vertical channel hole CH1, and the second portion VS1b may be disposed in the second vertical channel hole CH2. The second portion VS1b may be disposed on and connected to the first portion VS1a.

For each of the first and second portions VS1a and VS1b, a width in the first or second direction D1 or D2 may increase with increasing distance in the third direction D3. In an embodiment, the uppermost width of the first portion VS1a is larger than the lowermost width of the second portion VS1b. In other words, a side surface of each of the first vertical channel structures VS1 may have a stepped structure near a boundary between the first portion VS1a and the second portion VS1b. However, the inventive concept is not limited to this example, and in an embodiment, the side surface of each of the first vertical channel structures VS1 may have three or more stepped portions at different levels or may have a flat shape without a stepped portion.

Each of the first vertical channel structures VS1 may include a first barrier pattern Ba1, a data storage pattern DSP, and a vertical semiconductor pattern VSP, which are sequentially provided on an inner side surface of each of the vertical channel holes CH, an insulating gapfill pattern VI, which is provided to fill an internal space of the vertical semiconductor pattern VSP, and a conductive pad PAD, which is provided on the insulating gapfill pattern VI. The conductive pad PAD may be disposed in an empty space, which is defined or enclosed by the insulating gapfill pattern VI and the data storage pattern DSP (or the vertical semiconductor pattern VSP). In an embodiment, a top surface of each of the first vertical channel structures VS1 may have a circular, elliptical, or bar shape. The first barrier pattern Ba1 may be disposed adjacent to the stack ST to cover the side surfaces of the first and second interlayer insulating layers ILDa and ILDb and the side surfaces of the first and second gate electrodes ELa and ELb. The data storage pattern DSP may be provided to conformally cover an inner side surface of the first barrier pattern Ba1. For example, a portion of the data storage pattern DSP covering the inner side surface may have a uniform thickness. The vertical semiconductor pattern VSP may be provided to conformally cover an inner side surface of the data storage pattern DSP. For example, a portion of the vertical semiconductor pattern VSP that covers the inner side surface may have a uniform thickness.

The data storage pattern DSP may be provided between the first barrier pattern Ba1 and the vertical semiconductor pattern VSP. The vertical semiconductor pattern VSP may be disposed between the data storage pattern DSP and the insulating gapfill pattern VI. The vertical semiconductor pattern VSP may be shaped like a bottom-closed pipe or macaroni. The first barrier pattern Ba1 and the data storage pattern DSP may be shaped like a bottom-opened pipe or macaroni.

The first barrier pattern Ba1 may be formed of or include at least one of high-k dielectric materials whose dielectric constants are higher than silicon oxide and silicon nitride. The first barrier pattern Ba1 may be formed of or include at least one of, for example, hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate. In an embodiment, the first barrier pattern Ba1 may be formed of or include at least one of aluminum oxide or hafnium oxide.

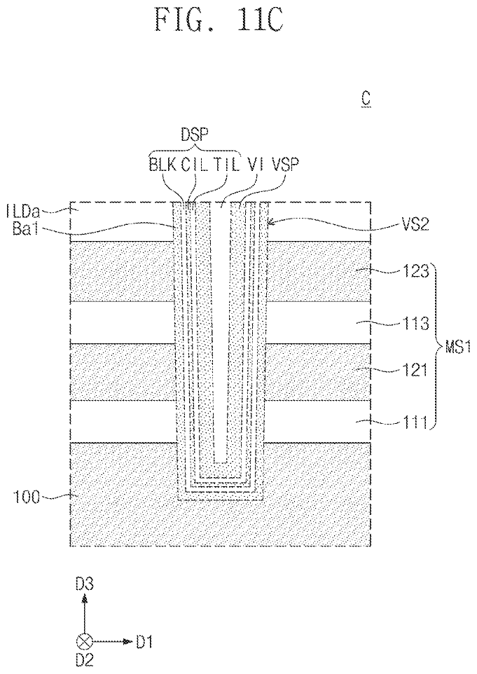

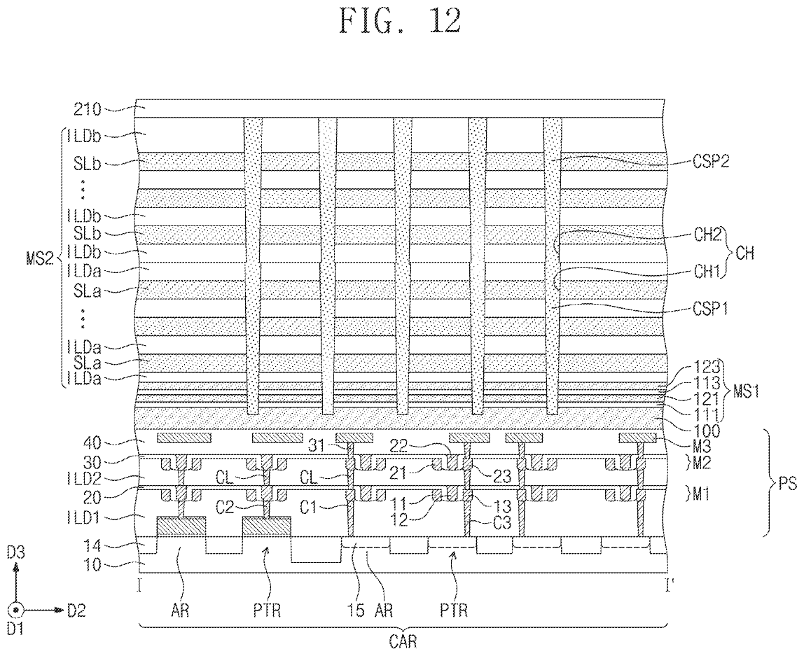

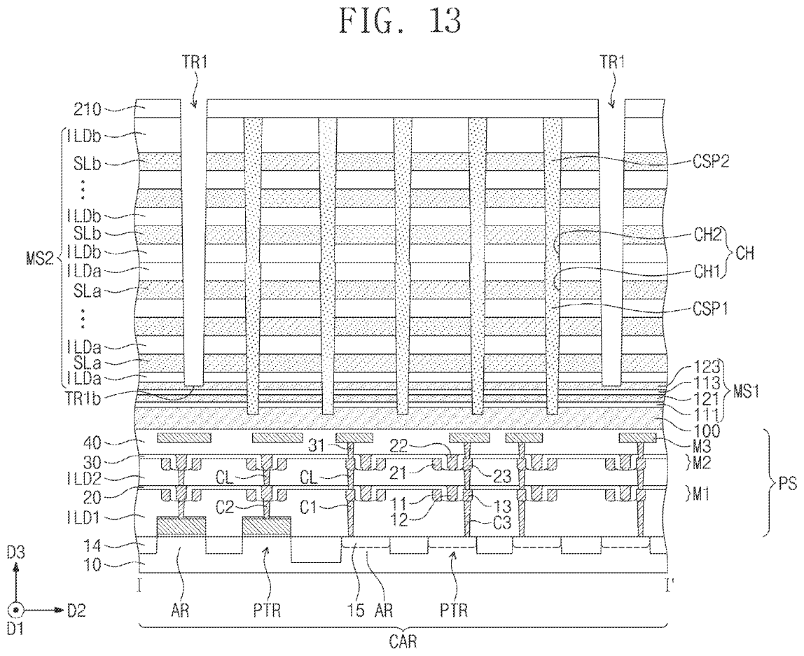

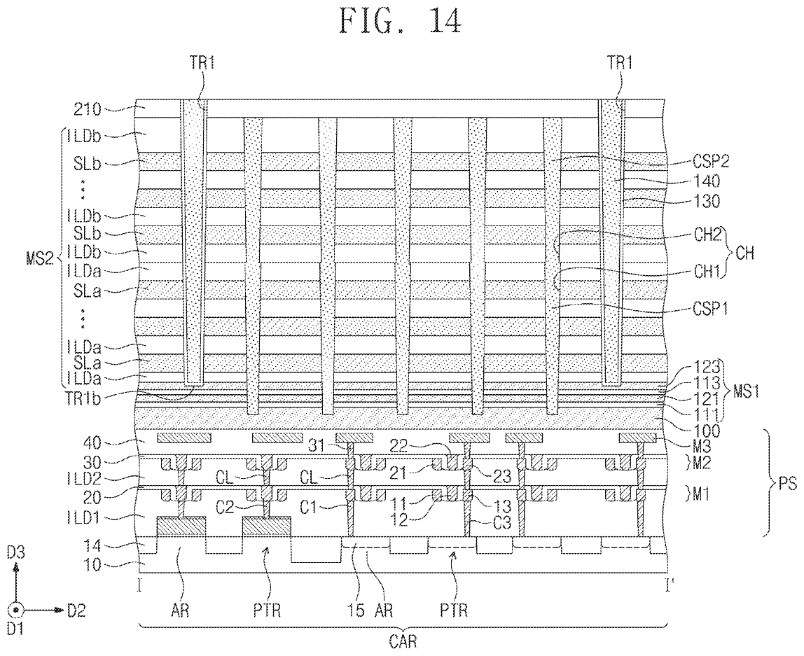

The vertical semiconductor pattern VSP may be formed of or include at least one of doped semiconductor materials or undoped or intrinsic semiconductor materials and may have a poly-crystalline or single-crystalline structure. As will be described with reference to FIG. 11B, the vertical semiconductor pattern VSP may be in contact with a portion of the source structure SC. The conductive pad PAD may be formed of or include at least one of doped semiconductor materials or conductive materials.

A plurality of second vertical channel structures VS2 may be disposed on the contact region CCR to penetrate a second insulating layer 170, the stack ST, and the first mold structure MS1. More specifically, the second vertical channel structures VS2 may penetrate the pad portions ELp of the first and second gate electrodes ELa and ELb. The second vertical channel structures VS2 may be disposed near cell contact plugs CCP, which will be described below. In an embodiment, the second vertical channel structures VS2 is not disposed on the cell array region CAR. The first and second vertical channel structures VS1 and VS2 may be formed at the same time and may have the same or substantially the same structure. However, in certain embodiments, the second vertical channel structures VS2 is omitted.

The second insulating layer 170 may be disposed on the contact region CCR to cover the stack ST and a portion of the first insulating layer 40. More specifically, the second insulating layer 170 may be disposed on the pad portions ELp of the first and second gate electrodes ELa and ELb to cover the stepwise structure of the stack ST. In an embodiment, the second insulating layer 170 has a flat or a substantially flat top surface. In an embodiment, a top surface of the second insulating layer 170 is coplanar with or substantially coplanar with the topmost surface of the stack ST. More specifically, the top surface of the second insulating layer 170 may be substantially coplanar with a top surface of the uppermost one of the second interlayer insulating layers ILDb of the stack ST.

The second insulating layer 170 may include an insulating layer or a plurality of stacked insulating layers. The second insulating layer 170 may be formed of or include at least one of insulating materials (e.g., silicon oxide, silicon nitride, silicon oxynitride, and/or low-k dielectric materials). In an embodiment, the second insulating layer 170 is formed of or includes an insulating material different from the first and second interlayer insulating layers ILDa and ILDb of the stack ST. In the case where the first and second interlayer insulating layers ILDa and ILDb of the stack ST include high-density plasma oxide, the second insulating layer 170 may be formed of or include tetraethylorthosilicate (TEOS).

A third insulating layer 230 may be provided on the second insulating layer 170 and the stack ST. The third insulating layer 230 may cover the top surface of the second insulating layer 170, the top surface of the uppermost one of the second interlayer insulating layers ILDb of the stack ST, and the top surfaces of the first and second vertical channel structures VS1 and VS2.

The third insulating layer 230 may include an insulating layer or a plurality of stacked insulating layers. The third insulating layer 230 may be formed of or include at least one of, for example, silicon oxide, silicon nitride, silicon oxynitride, and/or low-k dielectric materials. The third insulating layer 230 may be formed of or include substantially the same insulating material as the second insulating layer 170 and may include an insulating material different from the first and second interlayer insulating layers ILDa and ILDb of the stack ST.

In an embodiment, bit line contact plugs BLCP penetrate the third insulating layer 230 to be connected to the first vertical channel structures VS1. The cell contact plugs CCP may be provided to penetrate the third insulating layer 230 and the second insulating layer 170 and may be connected to the first and second gate electrodes ELa and ELb. Each of the cell contact plugs CCP may be provided to penetrate one of the first and second interlayer insulating layers ILDa and ILDb and may be in direct contact with one of the pad portions ELp of the first and second gate electrodes ELa and ELb. Each of the cell contact plugs CCP may be adjacent to a plurality of the second vertical channel structures VS2 and may be spaced apart from each other. The cell contact plugs CCP may correspond to the gate connection lines 3235 of FIG. 8.

In an embodiment, a peripheral contact plug TCP penetrates the third insulating layer 230, the second insulating layer 170, and at least a portion of the first insulating layer 40 to be electrically connected to the peripheral circuit transistor PTR of the peripheral circuit structure PS. A plurality of the peripheral contact plugs TCP may be provided, unlike that illustrated in the drawings. The peripheral contact plug TCP may be spaced apart from the second substrate 100, the source structure SC, and the stack ST in the first direction D1. The peripheral contact plug TCP may correspond to the penetration line 3245 of FIGS. 7 and 8.

In an embodiment, for the bit line contact plugs BLCP, the cell contact plugs CCP, and the peripheral contact plug TCP, a width in the first or second direction D1 or D2 increases with increasing distance in the third direction D3.

The bit lines BL may be disposed on the third insulating layer 230 and may be connected to the bit line contact plugs BLCP, respectively. The bit lines BL may correspond to the bit line BL of FIG. 5 and the bit lines 3240 of FIGS. 7 and 8.

First and second metal conductive lines CL1 and CL2, which are respectively connected to the cell and peripheral contact plugs CCP and TCP, may be disposed on the third insulating layer 230. The first and second metal conductive lines CL1 and CL2 may correspond to the conductive lines 3250 of FIG. 8.

The bit line contact plugs BLCP, the cell contact plugs CCP, the peripheral contact plug TCP, the bit lines BL, and the first and second metal conductive lines CL1 and CL2 may be formed of or include at least one of conductive materials (e.g., metallic materials). Although not shown, the bit lines BL, additional interconnection lines and additional vias, which are electrically connected to the first and second metal conductive lines CL1 and CL2, may be further disposed on the third insulating layer 230.

In the case where a plurality of stacks ST are provided, the separation structure 150 may be disposed in a second trench TR2, which is formed between the stacks ST and extends in the first direction D1. The separation structure 150 may be spaced apart from the first and second vertical channel structures VS1 and VS2 in the second direction D2. For example, a top surface of the separation structure 150 may be located at a level that is higher than top surfaces of the first and second vertical channel structures VS1 and VS2. In an embodiment, a bottom surface of the separation structure 150 is coplanar with or substantially coplanar with the top surface of the first source conductive pattern SCP1 and is located at a level higher than the top surface of the second substrate 100.

In an embodiment, a plurality of the separation structures 150 may be provided, and in this case, the separation structures 150 may be spaced apart from each other in the second direction D2 with the stack ST interposed therebetween. The separation structure 150 may correspond to the separation structures 3230 of FIGS. 7 and 8.

In an embodiment, a separation spacer 130 is disposed between the separation structure 150 and the stack ST to enclose the separation structure 150. The separation spacer 130 may be provided to conformally cover side surfaces of the first and second interlayer insulating layers ILDa and ILDb and the first and second gate electrodes ELa and ELb. For example, a portion of the separation spacer 130 covering the side surfaces may have a uniform thickness. The separation structure 150 may be formed of or include, for example, silicon oxide. The separation spacer 130 may be formed of or include a material having an etch selectivity with respect to the second source conductive pattern SCP2, the first and second semiconductor layers 121 and 123. The separation spacer 130 may be formed of or include, for example, silicon nitride.

FIG. 11A is an enlarged sectional view illustrating a portion of a three-dimensional semiconductor memory device according to an embodiment of the inventive concept and corresponding to a portion ‘A’ of FIG. 10A. FIG. 11B is an enlarged sectional view illustrating a portion of a three-dimensional semiconductor memory device according to an embodiment of the inventive concept and corresponding to a portion ‘B’ of FIG. 10A.

Each of FIGS. 10A, 11A, and 11B illustrate the source structure SC, which includes the first and second source conductive patterns SCP1 and SCP2, or the first vertical channel structure VS1, which includes the first barrier pattern Ba1, the data storage pattern DSP, the vertical semiconductor pattern VSP, the insulating gapfill pattern VI, and the lower data storage pattern DSPr. For convenience of description, one of the stacks ST and one of the first vertical channel structures VS1 will be described with reference to FIGS. 10A, 11A, and 11B, but the remaining ones of the stacks ST and the remaining ones of the first vertical channel structures VS1 may have the same or substantially the same features as those described with reference to FIGS. 10A, 11A, and 11B.

The data storage pattern DSP may include a blocking insulating layer BLK, a charge storing layer CIL, and a tunneling insulating layer TIL, which are sequentially stacked. The blocking insulating layer BLK may be adjacent to the stack ST or the source structure SC, and the tunneling insulating layer TIL may be adjacent to the vertical semiconductor pattern VSP. The charge storing layer CIL may be interposed between the blocking insulating layer BLK and the tunneling insulating layer TIL. The blocking insulating layer BLK may cover the inner side surface of the first barrier pattern Ba1. The blocking insulating layer BLK may be spaced apart from the first and second interlayer insulating layers ILDa and ILDb and the first and second gate electrodes ELa and ELb with the first barrier pattern Ba1 interposed therebetween. The first barrier pattern Ba1 may be provided to conformally cover an inner side surface of each of the vertical channel holes CH. For example, a portion of the first barrier pattern Ba1 covering the inner side surface may have a uniform thickness.

In an embodiment, the first barrier pattern Ba1 is disposed on the inner side surface of each of the vertical channel holes CH, not between each of the first and second interlayer insulating layers ILDa and ILDb and each of the first and second gate electrodes ELa and ELb. Thus, it may be possible to reduce a total thickness of the stack ST and thereby to reduce a size of a three-dimensional semiconductor memory device.

The blocking insulating layer BLK, the charge storing layer CIL, and the tunneling insulating layer TIL may extend in the third direction D3, between the first barrier pattern Ba1 and the vertical semiconductor pattern VSP. In an embodiment, a Fowler-Nordheim (FN) tunneling phenomenon, which is caused by a voltage difference between the vertical semiconductor pattern VSP and the first and second gate electrodes ELa and ELb, may be used to store or change data in the data storage pattern DSP. For example, the blocking insulating layer BLK and the tunneling insulating layer TIL may be formed of or include silicon oxide, and the charge storing layer CIL may be formed of or include silicon nitride or silicon oxynitride.

The first source conductive pattern SCP1 of the source structure SC may be in contact with the vertical semiconductor pattern VSP, and the second source conductive pattern SCP2 may be spaced apart from the vertical semiconductor pattern VSP with the first barrier pattern Ba1 and the data storage pattern DSP interposed therebetween. The first source conductive pattern SCP1 may be spaced apart from the insulating gapfill pattern VI with the vertical semiconductor pattern VSP interposed therebetween.

In an embodiment, the first source conductive pattern SCP1 includes protruding portions SCPbt located at a level higher than a bottom surface SCP2b of the second source conductive pattern SCP2 or lower than a bottom surface SCP1b of the first source conductive pattern SCP1. However, the protruding portions SCPbt may be located at a level lower than a top surface SCP2a of the second source conductive pattern SCP2. A surface of the protruding portion SCPbt, which is in contact with the data storage pattern DSP or the lower data storage pattern DSPr, may have a curved shape.

Referring to FIGS. 10A and 11A, a second barrier pattern Ba2 may be disposed between each of the first and second gate electrodes ELa and ELb and the first barrier pattern Ba1. The second barrier pattern Ba2 may extend in the third direction D3 between each of the first and second gate electrodes ELa and ELb and the first barrier pattern Ba1. In addition, the second barrier pattern Ba2 may extend on the upper and lower surfaces of each of the first and second gate electrodes ELa and ELb. The second barrier pattern Ba2 may be formed of or include a material that is different from the first and second gate electrodes ELa and ELb and the first barrier pattern Ba1. The second barrier pattern Ba2 may be formed of or include at least one of, for example, tantalum, tantalum nitride, tantalum silicon nitride, titanium, titanium nitride, titanium silicon nitride, tungsten, and tungsten nitride.

FIG. 11C is an enlarged view illustrating a portion of a three-dimensional semiconductor memory device according to an embodiment of the inventive concept and corresponding to a portion ‘C’ of FIG. 10B. In the following description, an element previously described with reference to FIGS. 11A and 11B may be identified by the same reference number without repeating an overlapping description thereof, for concise description.

FIGS. 10B and 11C illustrate one of the second vertical channel structures VS2 including the first barrier pattern Ba1, the data storage pattern DSP, the vertical semiconductor pattern VSP, and the insulating gapfill pattern VI, and the first mold structure MS1 including the first and second buffer insulating layers 111 and 113 and the first and second semiconductor layers 121 and 123.

The first and second buffer insulating layers 111 and 113 and the first and second semiconductor layers 121 and 123 may be spaced apart from the data storage pattern DSP with the first barrier pattern Ba1 interposed therebetween. In addition, the second substrate 100 may be spaced apart from the data storage pattern DSP with the first barrier pattern Ba1 interposed therebetween. In an embodiment, the first and second buffer insulating layers 111 and 113, the first and second semiconductor layers 121 and 123, and the second substrate 100 are not in contact with the data storage pattern DSP and the vertical semiconductor pattern VSP of each of the second vertical channel structures VS2.

FIGS. 12 to 20 are sectional views, which are taken along the line I-I′ of FIG. 9 to illustrate a method of fabricating a three-dimensional semiconductor memory device, according to an embodiment of the inventive concept. Hereinafter, a method of fabricating a three-dimensional semiconductor memory device, according to an embodiment of the inventive concept, will be described in more detail with reference to FIGS. 9, 10A, 10B, and 12 to 20.

Referring to FIGS. 9 and 12, the first substrate 10 including the cell array region CAR and the contact region CCR may be provided. The device isolation layer 14 may be formed in the first substrate 10 to define an active region. The formation of the device isolation layer 14 may include forming a trench in an upper portion of the first substrate 10 and filling the trench with a silicon oxide layer. For example, a portion of the first substrate 10 may be removed to form the trench.

The peripheral circuit transistors PTR may be formed on the active region AR defined by the device isolation layer 14. The first lower insulating layer ILD1 may be formed to cover the first substrate 10 and the peripheral circuit transistors PTR. The first lower insulating layer ILD1 may be formed by a layer-forming method (e.g., chemical vapor deposition (CVD) and physical vapor deposition (PVD) methods). The first interconnection layer M1 and the first to third contacts C1, C2, and C3 may be formed in the first lower insulating layer ILD1. The second lower insulating layer ILD2 may be formed on the first interconnection layer M1. The second interconnection layer M2 and the upper contacts CL may be formed in the second lower insulating layer ILD2. The first and second interconnection layers M1 and M2, the first to third contacts C1, C2, and C3, and the upper contacts CL may be formed by the same method as those described with reference to FIGS. 2A to 4C. The first insulating layer 40 may be formed on the second interconnection layer M2. The peripheral contacts 31 and the third interconnection layer M3 may be formed in the first insulating layer 40. The first insulating layer 40 may be formed by a layer-forming method (e.g., chemical vapor deposition (CVD) and physical vapor deposition (PVD) methods). The peripheral contacts 31 and the third interconnection layer M3 may be formed by substantially the same method as that described with reference to FIGS. 2A to 4C, but the inventive concept is not limited to this example.

The second substrate 100 may be formed on the first insulating layer 40. The second substrate 100 may be formed to extend from the cell array region CAR toward the contact region CCR.

A portion of the second substrate 100 disposed on the contact region CCR may be removed. The removal of the portion (i.e., a partial removal) of the second substrate 100 may include forming a mask pattern to cover a portion of the contact region CCR and the cell array region CAR and etching the second substrate 100 using the mask pattern as an etching mask. The partial removal of the second substrate 100 may be performed to form a region, in which the peripheral contact plug TCP described above will be disposed.

The first mold structure MS1 may be formed on the second substrate 100. The formation of the first mold structure MS1 may include sequentially stacking the first buffer insulating layer 111, the first semiconductor layer 121, the second buffer insulating layer 113, and the second semiconductor layer 123 on the second substrate 100. The first and second buffer insulating layers 111 and 113 may be formed of or include, for example, silicon oxide. The first and second semiconductor layers 121 and 123 may be formed of or include a material having an etch selectivity with respect to the first barrier pattern Ba1 to be described below. The first and second semiconductor layers 121 and 123 may be formed of or include a semiconductor material (e.g., silicon).

A second mold structure MS2 may be formed on the first mold structure MS1. The formation of the second mold structure MS2 may include alternately stacking the first interlayer insulating layers ILDa and first sacrificial layers SLa on the second substrate 100, forming the first vertical channel holes CH1 to penetrate the first interlayer insulating layers ILDa and the first sacrificial layers SLa, forming a first channel sacrificial pattern CSP1 to fill each of the first vertical channel holes CH1, alternately stacking the second interlayer insulating layers ILDb and second sacrificial layers SLb on the uppermost one of the first interlayer insulating layers ILDa, forming the second vertical channel holes CH2 to penetrate the second interlayer insulating layers ILDb and the second sacrificial layers SLb and to be respectively connected to the first vertical channel holes CH1, and forming a second channel sacrificial pattern CSP2 to fill each of the second vertical channel holes CH2 and to be connected to the first channel sacrificial pattern CSP1. The first vertical channel holes CH1 may penetrate not only the first interlayer insulating layers ILDa and the first sacrificial layers SLa but also the first mold structure MS1. For example, in an embodiment, the first vertical channel holes CH1 may further penetrate at least a portion of the second substrate 100.

Before the formation of the first and second vertical channel holes CH1 and CH2, a trimming process may be performed on the second mold structure MS2 on the contact region CCR. The trimming process may include forming a mask pattern to cover a portion of the top surface of the second mold structure MS2 on the cell array region CAR and the contact region CCR, patterning the second mold structure MS2 using the mask pattern as a patterning mask, reducing an area of the mask pattern, and patterning the second mold structure MS2 using the mask pattern having the reduced area as a patterning mask. In an embodiment, the steps of reducing the area of the mask pattern and patterning the second mold structure MS2 using the mask pattern may be repeated several times during the trimming process. As a result of the trimming process, the second mold structure MS2 may have a stepwise structure.

In an embodiment, the first and second sacrificial layers SLa and SLb are formed of or include an insulating material that is different from the first and second interlayer insulating layers ILDa and ILDb. The first and second sacrificial layers SLa and SLb may be formed of or include a material having an etch selectivity with respect to the first and second interlayer insulating layers ILDa and ILDb. For example, the first and second sacrificial layers SLa and SLb may be formed of silicon nitride, and the first and second interlayer insulating layers ILDa and ILDb may be formed of silicon oxide. In an embodiment, the first and second sacrificial layers SLa and SLb have the same or substantially the same thickness, and the first and second interlayer insulating layers ILDa and ILDb have at least two different thicknesses that are determined depending on their vertical positions.

A first insulating pattern 210 may be formed on the second mold structure MS2. The first insulating pattern 210 may be formed to cover the top surface of the second mold structure MS2 (i.e., the top surface of the uppermost one of the second interlayer insulating layers ILDb) and the top surface of the second channel sacrificial pattern CSP2.

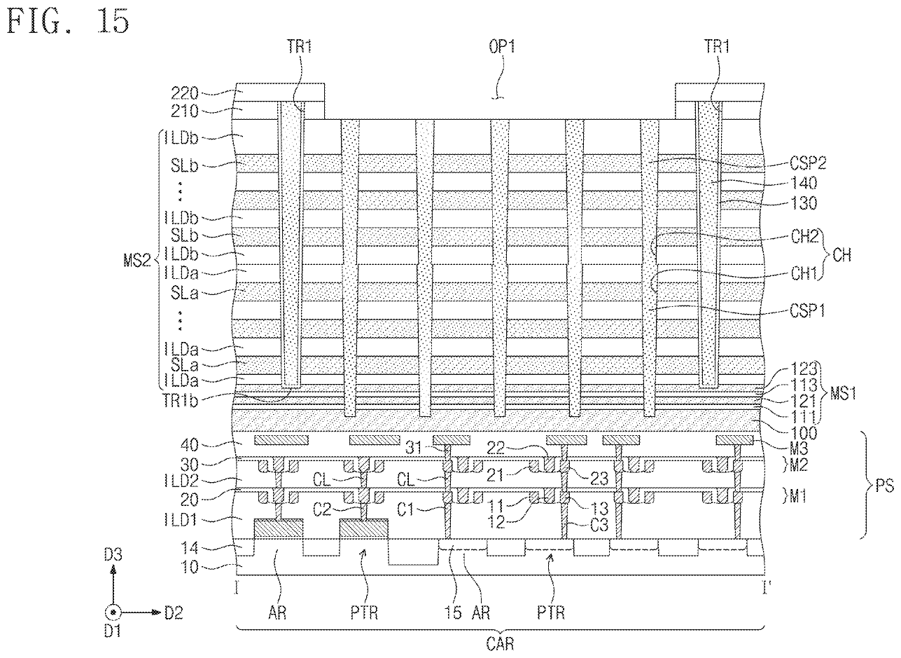

Referring to FIGS. 9 and 13, a first trench TR1 may be formed to penetrate the first insulating pattern 210 and the second mold structure MS2. For example, a portion of the first insulating pattern 210 and the second mold structure MS2 may be removed to form the first trench TR1. In an embodiment, the first trench TR1 may be formed to further penetrate at least a portion of the first mold structure MS1 (more specifically, at least a portion of the second semiconductor layer 123). For example, a bottom surface TR1b of the first trench TR1 may be located at a level lower than a bottom surface of the second mold structure MS2 (i.e., a bottom surface of the lowermost one of the first interlayer insulating layers ILDa) and a top surface of the first mold structure MS1. The first trench TR1 may be formed to expose side surfaces of the first and second interlayer insulating layers ILDa and ILDb and side surfaces of the first and second sacrificial layers SLa and SLb. The first trench TR1 may extend from the cell array region CAR toward the contact region CCR.

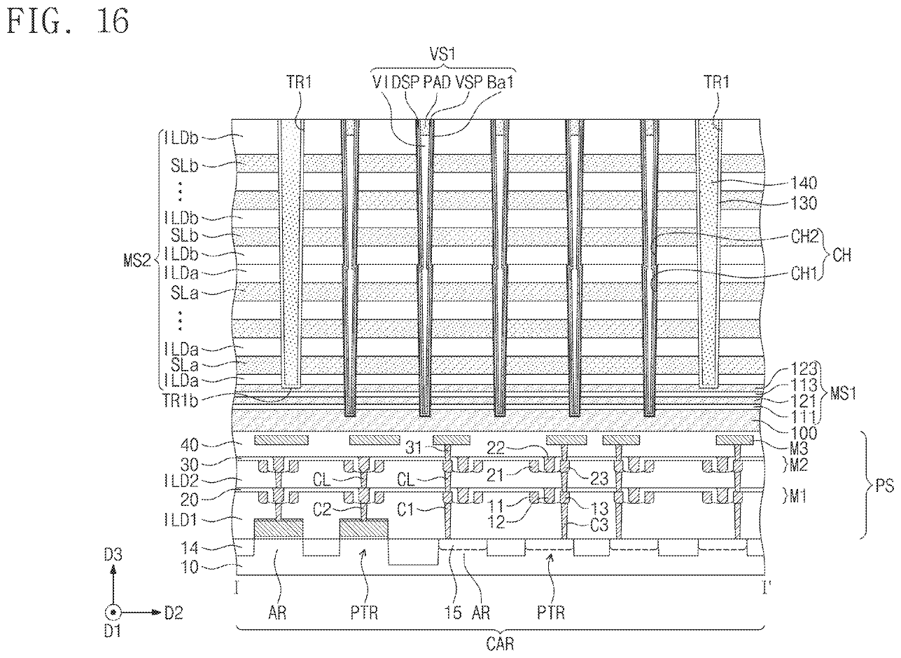

Referring to FIG. 14, the first and second sacrificial layers SLa and SLb exposed through the first trench TR1 may be selectively removed. The selective removal of the first and second sacrificial layers SLa and SLb may be performed through a wet etching process using etching solution. The first and second gate electrodes ELa and ELb may be formed to fill empty spaces, which are formed by removing the first and second sacrificial layers SLa and SLb. As a result, the stack ST including the first and second gate electrodes ELa and ELb and the first and second interlayer insulating layers ILDa and ILDb may be formed.

The formation of the first and second gate electrodes ELa and ELb may include forming the second barrier pattern Ba2 described with reference to FIG. 11A. The second barrier pattern Ba2 may be formed to conformally cover top and bottom surfaces of the first and second interlayer insulating layers ILDa and ILDb and side surfaces of the first and second channel sacrificial patterns CSP1 and CSP2 and to at least partially fill the empty spaces, which are formed by removing the first and second sacrificial layers SLa and SLb.

The first and second gate electrodes ELa and ELb may be formed before the first and second vertical channel structures VS1 and VS2 to be described later, and this may make it possible to prevent the first and second vertical channel structures VS1 and VS2 from being partially etched when the first and second sacrificial layers SLa and SLb are removed. Accordingly, it may be possible to increase electrical and reliability characteristics of the three-dimensional semiconductor memory device according to an embodiment of the inventive concept.

A separation spacer 130 and a sacrificial separation pattern 140 may be formed to fill the first trench TR1. The separation spacer 130 and the sacrificial separation pattern 140 may extend from the cell array region CAR toward the contact region CCR.

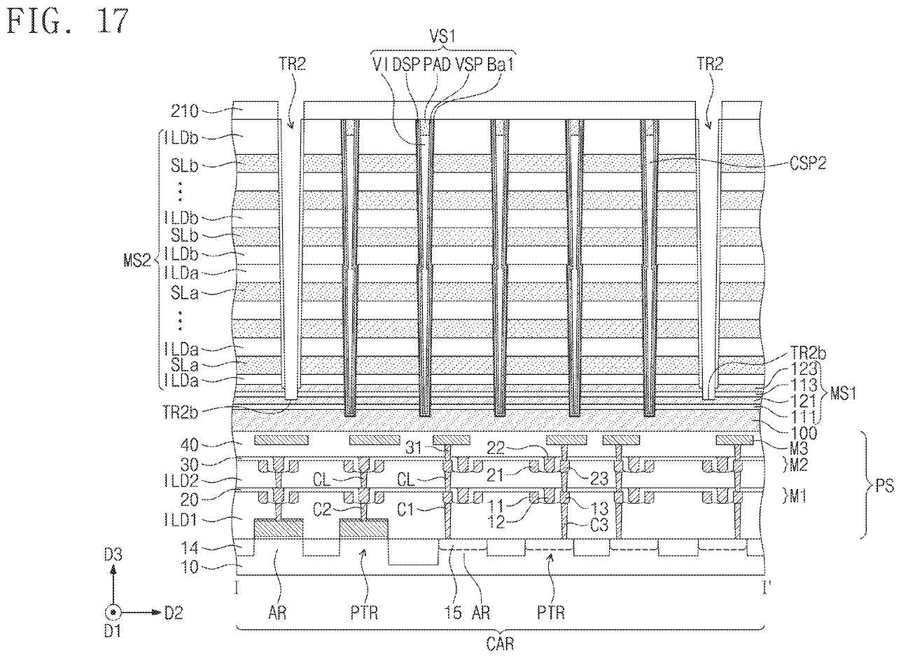

Referring to FIG. 15, a second insulating pattern 220 may be formed to cover a portion of a top surface of the first insulating pattern 210. An etching process may be performed using the second insulating pattern 220 as a mask. As a result of the etching process, a first opening OP1 may be formed. The first opening OP1 may be formed to expose a portion of the top surface of the stack ST and the top surface of the second channel sacrificial pattern CSP2. In an embodiment, the first opening OP1 does not expose the separation spacer 130 and the sacrificial separation pattern 140. In other words, the first and second insulating patterns 210 and 220 may be formed to cover the separation spacer 130 and the sacrificial separation pattern 140.

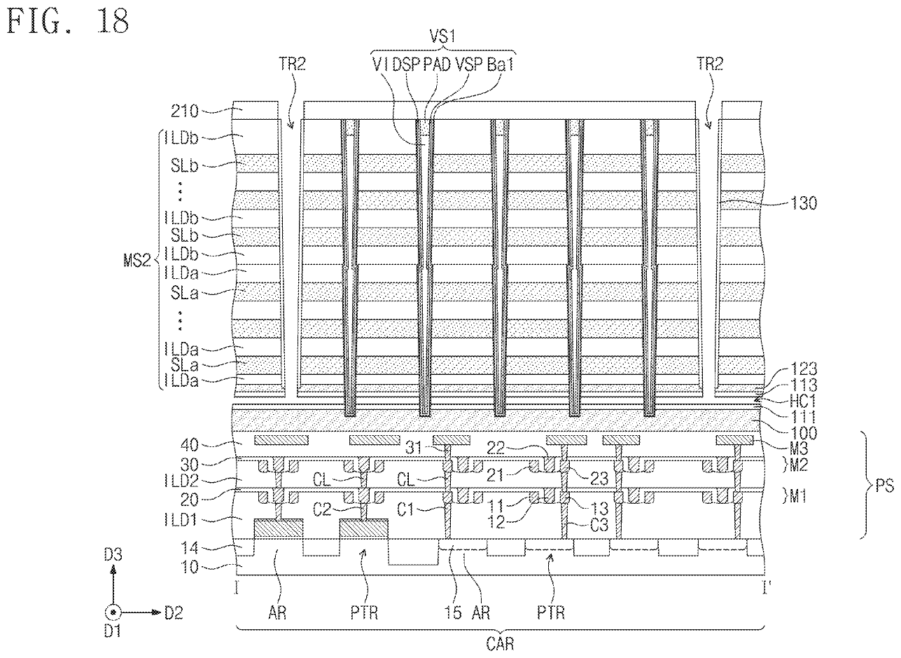

Referring to FIGS. 15 and 16, the second and first channel sacrificial patterns CSP2 and CSP1 exposed through the first opening OP1 may be removed. The first vertical channel structures VS1 may be formed on the cell array region CAR to fill empty spaces (i.e., the vertical channel holes CH), which are formed by the removing of the first and second channel sacrificial patterns CSP1 and CSP2. Similarly, the second vertical channel structures VS2 may be formed on the contact region CCR to fill the vertical channel holes CH.

The formation of each of the first and second vertical channel structures VS1 and VS2 may include forming the first barrier pattern Ba1 to conformally cover an inner side surface of each of the vertical channel holes CH, forming the data storage pattern DSP to conformally cover an inner side surface of the first barrier pattern Ba1, forming the vertical semiconductor pattern VSP to conformally cover a side surface of the data storage pattern DSP, forming the insulating gapfill pattern VI to fill at least a portion of a space enclosed by the vertical semiconductor pattern VSP, and forming the conductive pad PAD to fill a space enclosed by the vertical semiconductor pattern VSP and the insulating gapfill pattern VI.

After the formation of the first and second vertical channel structures VS1 and VS2, the first and second insulating patterns 210 and 220 may be removed. Furthermore, the separation spacer 130 and the sacrificial separation pattern 140 may also be partially etched during the removing of the first insulating pattern 210, and the top surface of the stack ST may be exposed to the outside.

Referring to FIGS. 9 and 17, a third insulating pattern 230 may be formed on the top surface of the stack ST. The third insulating pattern 230 may correspond to the third insulating layer 230 described with reference to FIGS. 10A and 10B.

The third insulating pattern 230 may be formed to expose a top surface of the sacrificial separation pattern 140 to the outside. The second trench TR2 may be formed by selectively removing the sacrificial separation pattern 140 exposed by the third insulating pattern 230. In an embodiment, at least a portion of the first mold structure MS1 disposed on the cell array region CAR may be removed during the process of removing the sacrificial separation pattern 140. However, in an embodiment, the first mold structure MS1 disposed the contact region CCR is not removed.

The second trench TR2 may extend from the cell array region CAR toward the contact region CCR. On the cell array region CAR, a bottom surface TR2b of the second trench TR2 may be located between a top surface of the first semiconductor layer 121 and the top surface of the second substrate 100.

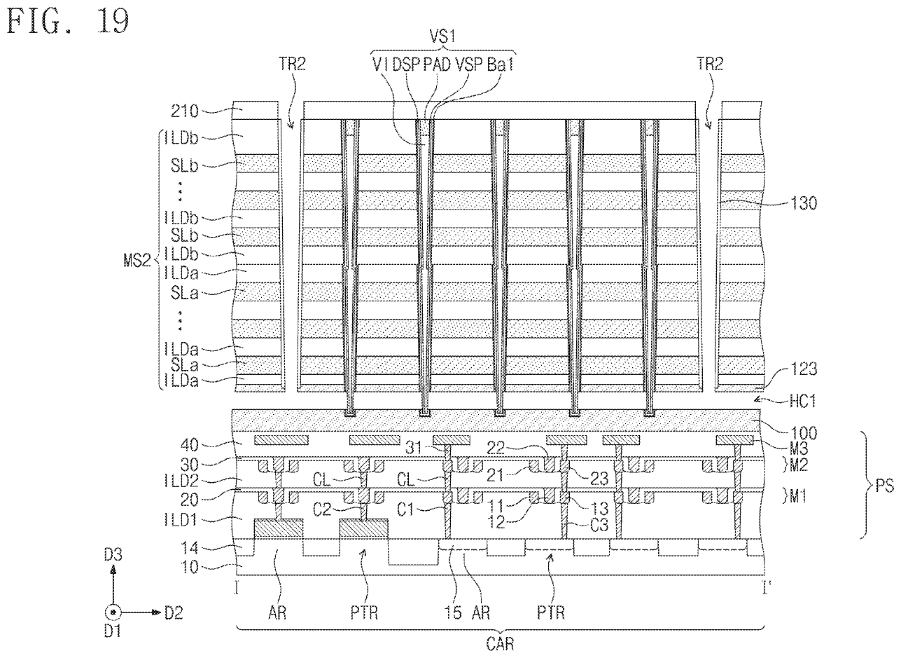

Referring to FIG. 18, the first semiconductor layer 121 exposed through the second trench TR2 may be selectively removed. The selective removal of the first semiconductor layer 121 may be performed through a wet etching process using etching solution. As a result of the removal of the first semiconductor layer 121, a first horizontal cavity HC1 may be formed between a top surface of the first buffer insulating layer 111 and a bottom surface of the second buffer insulating layer 113. The first horizontal cavity HC1 may be an empty space between the first and second buffer insulating layers 111 and 113. A portion of the first barrier pattern Ba1 of each of the first vertical channel structures VS1 may be exposed through the first horizontal cavity HC1.

Since the first semiconductor layer 121 has an etch selectivity with respect to the first barrier pattern Ba1, it may be possible to prevent or suppress the first barrier pattern Ba1 and the data storage pattern DSP, which is enclosed by the first barrier pattern Ba1, from being damaged in a process of forming the first horizontal cavity HC1.

The removal of the first semiconductor layer 121 may be performed on the cell array region CAR, and the first mold structure MS1 on the contact region CCR (especially, a portion of the first semiconductor layer 121 provided on the contact region CCR) may remain as it is.

Referring to FIGS. 18 and 19, the first and second buffer insulating layers 111 and 113 exposed through the first horizontal cavity HC1 may be removed to form a second horizontal cavity HC2. Here, the second horizontal cavity HC2 may be an empty space between the second substrate 100 and the second semiconductor layer 123. In addition, a portion of the first barrier pattern Ba1 and a portion of the data storage pattern DSP may be removed through the second horizontal cavity HC2. Accordingly, a portion of the vertical semiconductor pattern VSP of each of the first vertical channel structures VS1 may be exposed by the second horizontal cavity HC2.

The removal of the first and second buffer insulating layers 111 and 113 may be performed on the cell array region CAR, and the first mold structure MS1 on the contact region CCR (especially, a portion of each of the first and second buffer insulating layers 111 and 113 disposed on the contact region CCR) may remain as it is.

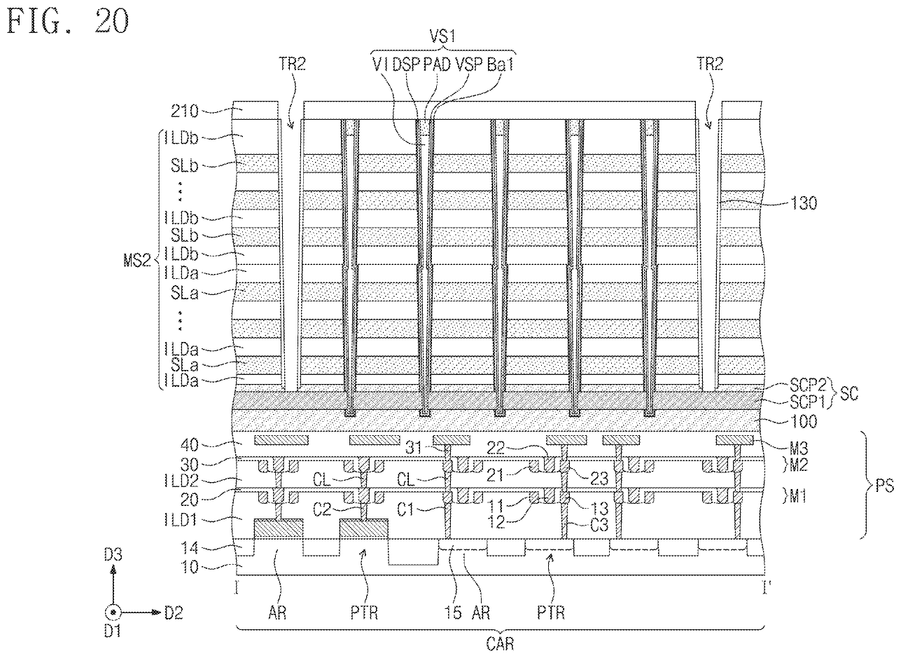

Referring to FIGS. 19 and 20, the first source conductive pattern SCP1 may be formed to fill the second horizontal cavity HC2. Although not shown, an air gap may be formed in the first source conductive pattern SCP1. The second semiconductor layer 123 disposed on the cell array region CAR may be referred to as the second source conductive pattern SCP2, and as a result, the source structure SC including the first and second source conductive patterns SCP1 and SCP2 may be formed.

Referring back to FIGS. 9, 10A, and 10B, the separation structure 150 may be formed to fill the second trench TR2. The top surface of the separation structure 150 may be coplanar with or substantially coplanar with a top surface of the third insulating layer 230.

Thereafter, the bit line contact plugs BLCP may be formed to penetrate the third insulating layer 230, the cell contact plugs CCP may be formed to penetrate the third insulating layer 230 and the second insulating layer 170, and the peripheral contact plug TCP may be formed to penetrate the third insulating layer 230, the second insulating layer 170, and at least a portion of the first insulating layer 40. The bit lines BL connected to the bit line contact plugs BLCP, the first metal conductive lines CL1 connected to the cell contact plugs CCP, and the second metal conductive line CL2 connected to the peripheral contact plug TCP may be formed on the third insulating layer 230.

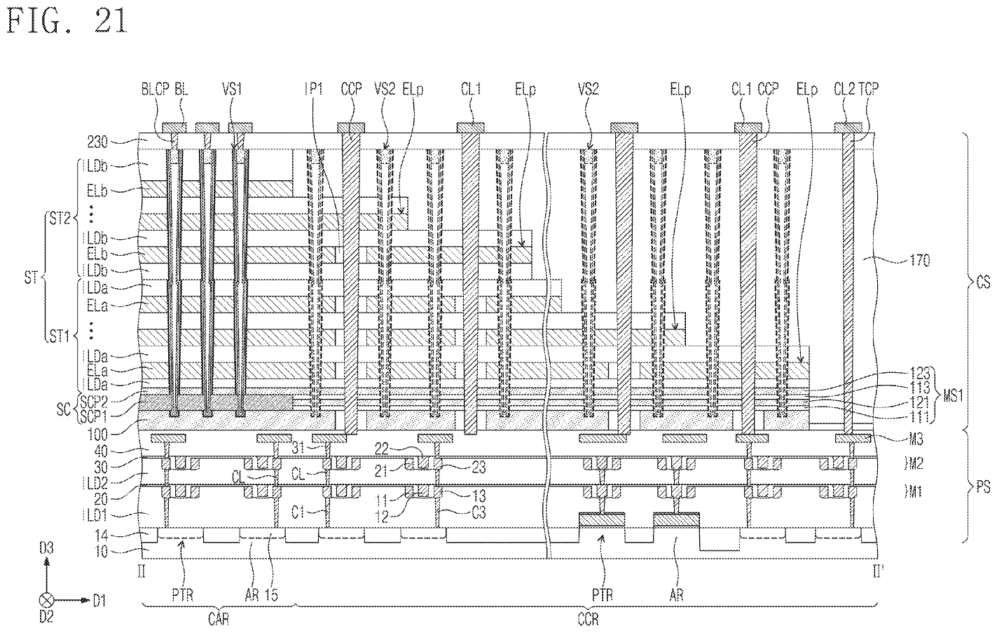

FIG. 21 is a sectional view, which is taken along the line II-II′ of FIG. 9 to illustrate a three-dimensional semiconductor memory device according to an embodiment of the inventive concept. In the following description, an element previously described with reference to FIGS. 9, 10A, and 10B may be identified by the same reference number without repeating an overlapping description thereof, for concise description.

Referring to FIGS. 9 and 21, each of the cell contact plugs CCP may penetrate the third insulating layer 230, the second insulating layer 170, the stack ST, the first mold structure MS1, and the second substrate 100 to be electrically connected to the peripheral circuit transistors PTR of the peripheral circuit structure PS. In an embodiment, the cell contact plugs CCP have bottom surfaces that are located at a level lower than a bottom surface of the stack ST. Each of the cell contact plugs CCP may be in contact with and electrically connected to a corresponding one of the gate electrodes ELa and ELb. In an embodiment, each of the cell contact plugs CCP may be in contact with the pad portion ELp of the uppermost one of the gate electrodes ELa and ELb provided in the stepwise shape.

Each of the cell contact plugs CCP may be spaced apart from the gate electrodes ELa and ELb, which are located below the pad portions ELp, in a horizontal direction (e.g., in all directions parallel to a plane defined by the first and second directions D1 and D2) with a first insulating pattern IP1 interposed therebetween and may be electrically disconnected from the gate electrodes ELa and ELb below the pad portions ELp. Each of the cell contact plugs CCP may be separated from the second substrate 100 in a horizontal direction with a second insulating pattern IP2 interposed therebetween and may be electrically disconnected from the second substrate 100. The first and second insulating patterns IP1 and IP2 may be formed of or include the same material as the interlayer insulating layers ILDa and ILDb of the stack ST. In an embodiment, a bottom surface of each of the cell contact plugs CCP is located at a level lower than a bottom surface of the second substrate 100. In an embodiment, a height of each of the cell contact plugs CCP in the third direction D3 is equal to or substantially equal to a height of the peripheral contact plug TCP in the third direction D3.

The formation of the cell and peripheral contact plugs CCP and TCP may include forming vertical holes to penetrate the third insulating layer 230, the second insulating layer 170, the stack ST, and the second substrate 100 and filling the vertical holes with a conductive material. The vertical holes, in which the cell and peripheral contact plugs CCP and TCP are provided, may be formed by the afore-described etching process for forming the vertical channel holes CH. In this case, it may be possible to reduce an iteration number of a high-aspect-ratio etching process and a process difficulty in a fabrication process.

According to an embodiment of the inventive concept, first to third conductive lines, which are adjacent to each other in a horizontal direction, may be formed as a single unit, and the second conductive line may be formed in a self-aligned manner between the first and third conductive lines. In this case, it may be possible to overcome technical difficulties (e.g., a patterning limitation of a photolithography process) in a process of forming the first to third conductive lines having a fine pitch. Furthermore, an interconnection layer including the first to third conductive lines may be formed with an increased integration density, thereby increasing an integration density of a semiconductor device.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a first substrate;
a transistor disposed on the first substrate; and
a first interconnection layer connected to the transistor,
wherein the first interconnection layer comprises a first conductive line, a second conductive line, and a third conductive line, which are spaced apart from each other in a first direction parallel to a top surface of the first substrate,
wherein the second conductive line is disposed between the first conductive line and the third conductive line, and
wherein a top surface of the second conductive line is located at a height higher than top surfaces of the first and third conductive lines with respect to the top surface of the first substrate.

2. The semiconductor device of claim 1, further comprising a second interconnection layer disposed on the first interconnection layer,
wherein the second interconnection layer comprises a fourth conductive line, a fifth conductive line, and a sixth conductive line, which are spaced apart from each other in the first direction,
the fifth conductive line is disposed between the fourth conductive line and the sixth conductive line; and
a top surface of the fifth conductive line is located at a height higher than top surfaces of the fourth and sixth conductive lines with respect to the top surface of the first substrate.

3. The semiconductor device of claim 1, wherein the top surfaces of the first and third conductive lines are located at a same level.

4. The semiconductor device of claim 2, wherein the top surfaces of the fourth and sixth conductive lines are located at a same level.

5. The semiconductor device of claim 1, further comprising:
a contact connected to a terminal of the transistor; and
a first pattern insulating layer interposed between the first and second conductive lines and between the second and third conductive lines, wherein the first pattern insulating layer extends along a bottom surface of the second conductive line,
wherein the second conductive line penetrates the first pattern insulating layer to be electrically connected to the contact.

6. The semiconductor device of claim 2, further comprising:
a contact connected to one of the conductive lines of the first interconnection layer; and
a second pattern insulating layer interposed between the fourth and fifth conductive lines and between the fifth and sixth conductive lines, wherein the second pattern insulating layer extends along a bottom surface of the fifth conductive line,
wherein the fifth conductive line penetrates the second pattern insulating layer to be electrically connected to the contact.

7. The semiconductor device of claim 1, wherein the first to third conductive lines comprise tungsten (W).

8. A method of fabricating a semiconductor device, comprising:
forming a first lower insulating layer on a first substrate;
forming a first interconnection trench and a third interconnection trench in the first lower insulating layer to be spaced apart from each other in a first direction parallel to a top surface of the first substrate;
forming first sacrificial patterns to fill the first and third interconnection trenches, respectively;
forming a second interconnection trench to penetrate a portion of each of the first sacrificial patterns and the first lower insulating layer between the first sacrificial patterns;
forming a second sacrificial pattern to fill the second interconnection trench;
removing the first sacrificial patterns to expose a portion of the first interconnection trench and a portion of the third interconnection trench;
forming a first conductive line in the portion of the first interconnection trench and a third conductive line in the portion of the third interconnection trench;
removing the second sacrificial pattern to expose the second interconnection trench;
forming a first pattern insulating layer on the first lower insulating layer to fill a portion of the second interconnection trench; and
forming a second conductive line on the first pattern insulating layer to fill a remaining portion of the second interconnection trench.

9. The method of claim 8, wherein the first and third conductive lines are formed to have a top surface located at a same level.

10. The method of claim 8, wherein a top surface of the second conductive line is located at a level higher than top surfaces of the first and third conductive lines with respect to the top surface of the first substrate.

11. The method of claim 8, wherein the first and second sacrificial patterns comprises materials having an etch selectivity with respect to each other.

12. The method of claim 8, wherein the first sacrificial patterns include a material comprising one of silicon, silicon carbide, and silicon nitride, and
the second sacrificial pattern comprises one of silicon, silicon carbide, and silicon nitride that different from the material of the first sacrificial patterns.

13. The method of claim 8, further comprising:
forming a contact to be electrically connected to the first substrate, in the first lower insulating layer; and
removing a portion of the first pattern insulating layer on a bottom surface of the second interconnection trench to expose a top surface of the contact, after the forming of the first pattern insulating layer and before the forming of the second conductive line.

14. The method of claim 13, wherein the portion of the first pattern insulating layer disposed on the bottom surface of the second interconnection trench is removed by an anisotropic etching process.

15. A semiconductor device, comprising:
a first substrate;
a peripheral circuit structure disposed on the first substrate;
a second substrate disposed on the peripheral circuit structure;
a stack including interlayer insulating layers and gate electrodes, which are alternatingly stacked on the second substrate; and
first vertical channel structures penetrating the stack to be electrically connected to the second substrate,
wherein the peripheral circuit structure comprises:
a plurality of peripheral circuit transistors disposed on the first substrate; and
a first interconnection layer connected to the peripheral circuit transistors,
wherein the first interconnection layer comprises a first conductive line, a second conductive line, and a third conductive line, which are spaced apart from each other in a first direction parallel to a top surface of the first substrate,
wherein the second conductive line is disposed between the first conductive line and the third conductive line, and
wherein a top surface of the second conductive line is located at a level higher than top surfaces of the first and third conductive lines with respect to the top surface of the first substrate.

16. The semiconductor device of claim 15, further comprising a second interconnection layer disposed on the first interconnection layer,
wherein the second interconnection layer comprises a fourth conductive line, a fifth conductive line, and a sixth conductive line, which are spaced apart from each other in the first direction,
wherein the fifth conductive line is disposed between the fourth and sixth conductive lines; and
wherein a top surface of the fifth conductive line is located at a level higher than top surfaces of the fourth and sixth conductive lines with respect to the top surface of the first substrate.

17. The semiconductor device of claim 15, wherein the top surfaces of the first and third conductive lines are located at a same level.

18. The semiconductor device of claim 15, further comprising:
a contact connected to a terminal of the peripheral circuit transistor; and
a first pattern insulating layer interposed between the first and second conductive lines and between the second and third conductive lines, wherein the first pattern insulating layer extends along a bottom surface of the second conductive line,
wherein the second conductive line penetrates the first pattern insulating layer to be electrically connected to the contact.

19. The semiconductor device of claim 16, further comprising:
a contact connected to one of the conductive lines of the first interconnection layer; and
a second pattern insulating layer interposed between the fourth and fifth conductive lines and between the fifth and sixth conductive lines, wherein the second pattern insulating layer extends along a bottom surface of the fifth conductive line,
wherein the fifth conductive line penetrates the second pattern insulating layer to be electrically connected to the contact.

20. The semiconductor device of claim 16, wherein the top surfaces of the fourth and sixth conductive lines are located at a same level.
